(19) United States
(12) Patent Application Publication
(10) Pub. No.: US 2025/0230176 A1
(43) Pub. Date: Jul. 17, 2025

(54) SILICON PRECURSOR COMPOUND IN ASYMMETRIC STRUCTURE, METHOD FOR PREPARING THE SAME, AND METHOD FOR PREPARING A SILICON-CONTAINING THIN FILM

(71) Applicant: MERCK PATENT GMBH, DARMSTADT (DE)

(72) Inventors: BYEONG-IL YANG, DAEJEON (KR); HEE-YEON JEONG, Chungcheongbuk-do (KR); YEONG-JU SEONG, Chungcheongnam-do (KR); JANG-WOO SEO, EUMSEONG (KR); SEONG-HAK CHEON, Chungcheongbuk-do (KR); JOO-YONG KIM, DAEJEON (KR); YOUNG-HUN BYUN, Chungcheongbuk-do (KR)

(21) Appl. No.: 19/093,076

(22) Filed: Mar. 27, 2025

Related U.S. Application Data
(63) Continuation of application No. PCT/KR2023/014790, filed on Sep. 26, 2023.

(30) Foreign Application Priority Data
Sep. 27, 2022 (KR) 10-2022-0122367

(51) Int. Cl. C07F 7/18; C07F 7/02; C23C 16/40; C23C 16/455

(52) U.S. Cl. CPC C07F 7/1888; C07F 7/025; C23C 16/402; C23C 16/45553

(57) ABSTRACT

The present invention relates to a silicon precursor compound in an asymmetric structure containing an alkoxide capable of preparing a silicon-containing thin film with high quality, to a method for preparing the same, and to a method for preparing a silicon-containing thin film using the silicon precursor compound in an asymmetric structure containing an alkoxide.

### CROSS-REFERENCE TO RELATED APPLICATION

This application is a Continuation under 35 USC § 111(a) of International Patent Application No. PCT/KR2023/014790 filed Sep. 26, 2023, which claims priority to the KR Application No. 10-2022-0122367 filed Sep. 27, 2022. The entire contents of these applications are incorporated herein by reference in their entirety.

### TECHNICAL FIELD

The present invention relates to a silicon precursor compound in an asymmetric structure containing an alkoxide, to a method for preparing the same, and to a method for preparing a silicon-containing thin film using the silicon precursor compound.

### BACKGROUND ART

Silicon-containing thin films are used as semiconductor substrates, diffusion masks, anti-oxidation films, and dielectric films in the semiconductor technologies such as microelectronic devices such as RAM (memory and logic chips), flat panel displays including thin film transistors (TFT), and solar energy.

In particular, in accordance with the high integration of semiconductor devices, silicon-containing thin films having various performances are required. As the aspect ratio increases with the high integration of semiconductor devices, there has been a problem in that the deposition of a silicon-containing thin film using a conventional precursor does not meet the required performance.

It is difficult to achieve excellent step coverage and thickness control for highly integrated semiconductor devices with thin film deposition using conventional precursors. There is also a problem in that impurities are contained in the thin film.

Accordingly, there has been a demand for the development of various silicon precursor compounds depending on physical and chemical properties as a silicon precursor necessary for forming a high-quality silicon-containing film.

### DISCLOSURE OF INVENTION

### Technical Problem

An object of the present invention is to provide a novel silicon precursor compound in an asymmetric structure containing an alkoxide capable of preparing a silicon-containing thin film with excellent quality and a method for preparing the same.

In addition, another object is to provide a method for preparing a silicon-containing thin film using the novel silicon precursor compound in an asymmetric structure containing an alkoxide.

### Technical Solution

The silicon precursor compound of the present invention for accomplishing the above object is characterized in that it is represented by the following Formula 1.

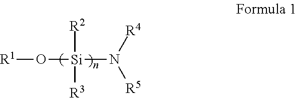

In Formula 1, n is 1 or 2; R¹ is any one selected from a linear or branched, saturated or unsaturated hydrocarbon group having 1 to 4 carbon atoms, an isomer thereof, and NR⁷R⁸; R² and R³ are each any one selected from hydrogen (H), chlorine (Cl), methyl (Me), methoxy (MeO), ethoxy (EtO), n-propoxy, isopropoxy (^{iso}PrO), n-butoxy, isobutoxy (^{iso}BuO), sec-butoxy (^{sec}BuO), tert-butoxy (^{tert}BuO), and NR⁷R⁸; R⁴ is a linear or branched, saturated or unsaturated hydrocarbon group or an isomer thereof; R⁵ is any one selected from methyl (Me), ethyl (Et), iso-propyl (^{iso}Pr), SiMe₃, SiHMe₂, SiH₂Me, SiH₃, SiHClMe, SiHCl₂, SiMe₂CH₂CH₃, SiMe₂CH═CH₂, and SiHMeCH═CH₂; and R⁷ and R⁸ in NR⁷R⁸ are each any one selected from methyl (Me), ethyl (Et), and iso-propyl (^{iso}Pr). In the silicon precursor compound of the present invention, R⁴ and R⁵ may be different from each other, preferably, R⁴ and R⁵ are different from each other.

The silicon precursor compound of the present invention is preferably selected from the group consisting of the following compounds (1) to (56).

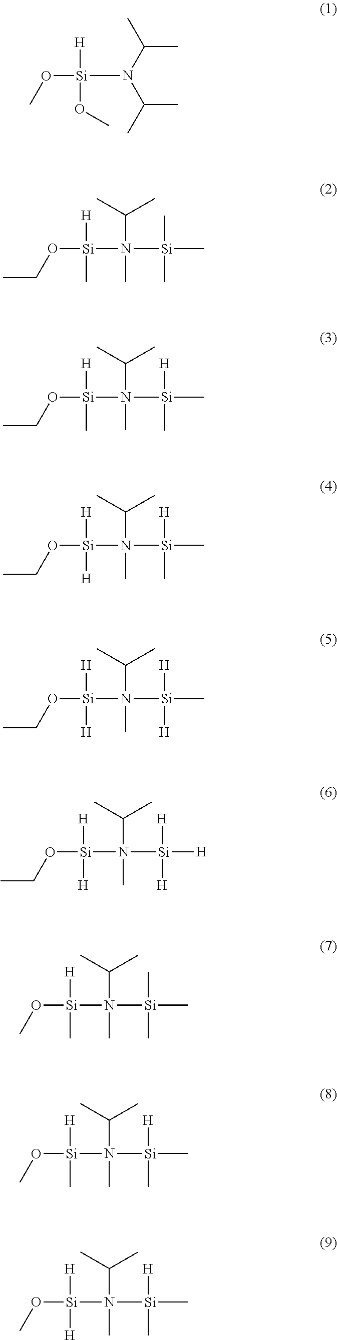

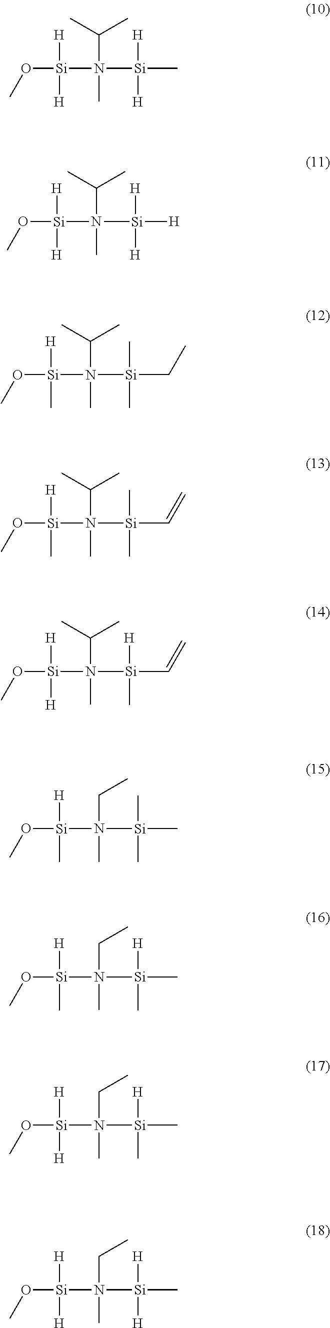

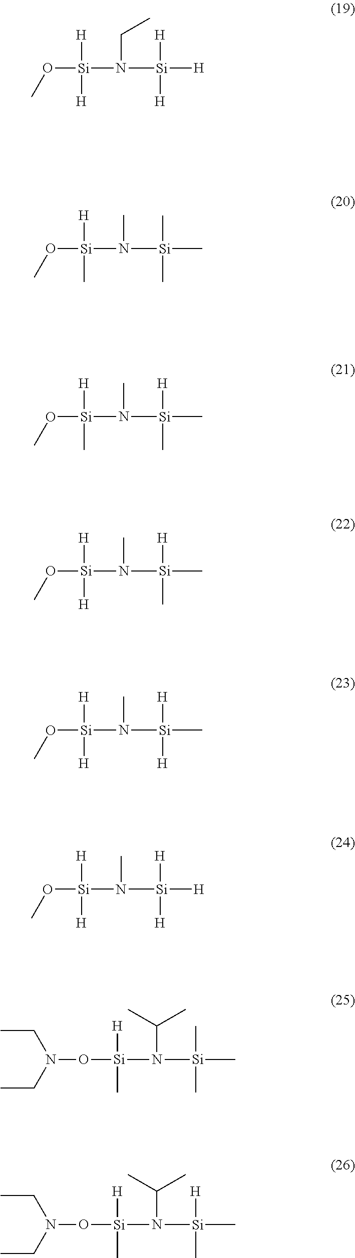

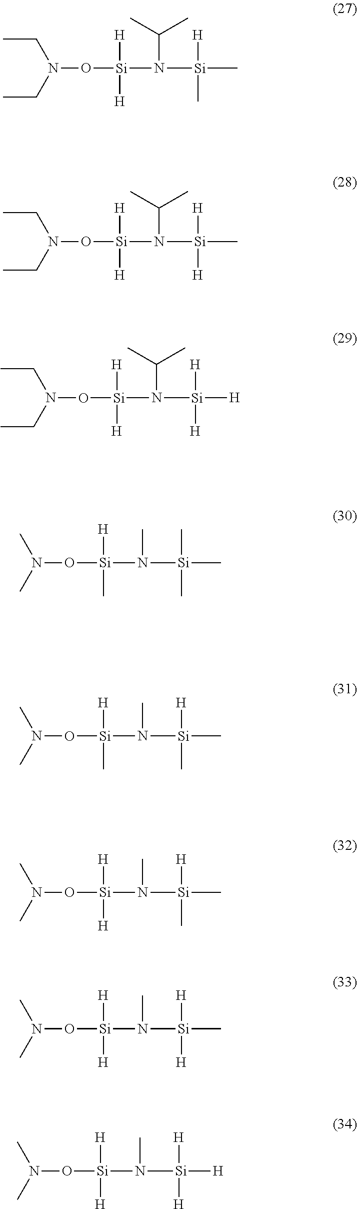

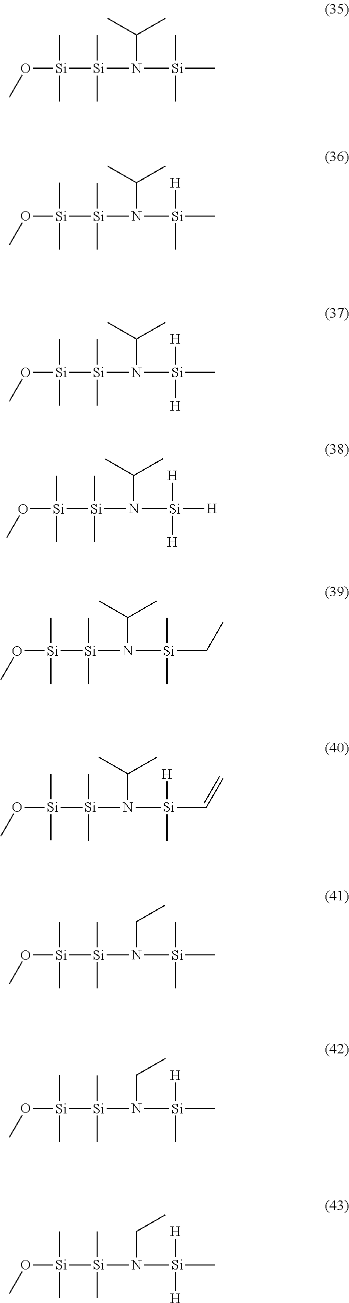

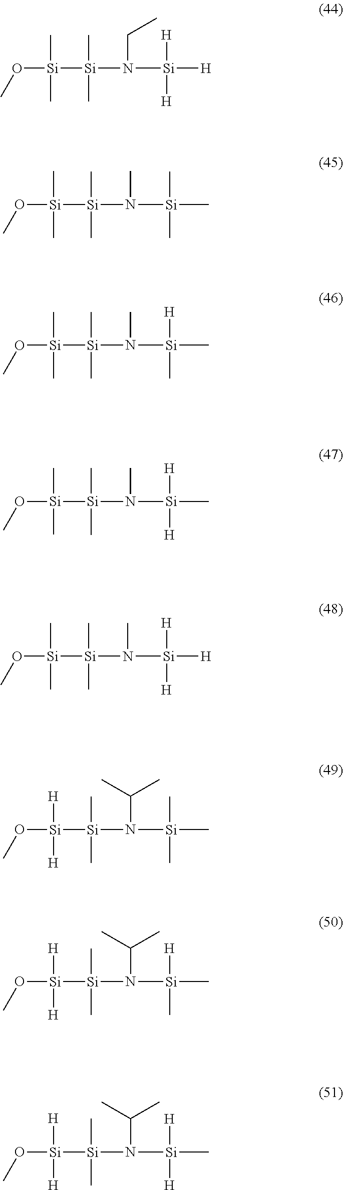

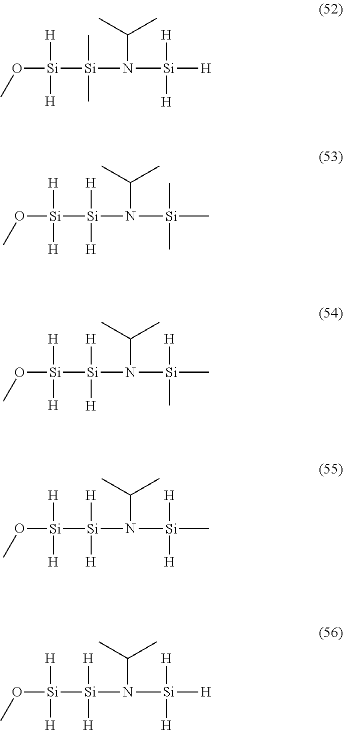

The method for preparing a silicon precursor compound of the present invention for accomplishing another object may comprise reacting an alkoxide compound with a secondary amine or reacting an alkoxide compound with an alkylaminosilane to prepare a silicon precursor compound represented by Formula 1.

The alkoxide compound is preferably a compound represented by the following Formula 4.

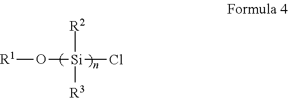

In Formula 4, n is 1 or 2; R¹ is any one selected from a linear or branched, saturated or unsaturated hydrocarbon group having 1 to 4 carbon atoms, an isomer thereof, and NR⁷R⁸; R² and R³ are each any one selected from hydrogen (H), chlorine (Cl), methyl (Me), methoxy (MeO), ethoxy (EtO), n-propoxy, isopropoxy (^{iso}PrO), n-butoxy, isobutoxy (^{iso}BuO), sec-butoxy (^{sec}BuO), tert-butoxy (^{tert}BuO), and NR⁷R⁸. R⁷ and R⁸ in NR⁷R⁸ are each any one selected from methyl (Me), ethyl (Et), and iso-propyl (^{iso}Pr).

In the method for preparing a silicon precursor compound, the reaction of the alkoxide compound with the secondary amine may prepare a silicon precursor compound represented by the following Formula 8.

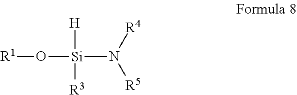

In Formula 8, R¹ is any one selected from a linear or branched, saturated or unsaturated hydrocarbon group having 1 to 4 carbon atoms, an isomer thereof, and NR⁷R⁸; R³ is any one selected from hydrogen (H), chlorine (Cl), methyl (Me), methoxy (MeO), ethoxy (EtO), n-propoxy, isopropoxy (^{iso}PrO), n-butoxy, isobutoxy (^{iso}BuO), sec-butoxy (^{sec}BuO), tert-butoxy (^{tert}BuO), and NR⁷R⁸; R⁴ is a linear or branched, saturated or unsaturated hydrocarbon group or an isomer thereof; R⁵ is any one selected from methyl (Me), ethyl (Et), iso-propyl (^{iso}Pr), SiMe₃, SiHMe₂, SiH₂Me, SiH₃, SiHClMe, SiHCl₂, SiMe₂CH₂CH₃, SiMe₂CH═CH₂, and SiHMeCH═CH₂; and R⁷ and R⁸ in NR⁷R⁸ are each any one selected from methyl (Me), ethyl (Et), and iso-propyl (^{iso}Pr).

In the method for preparing a silicon precursor compound, the reaction of the alkoxide compound with the alkylaminosilane may prepare a silicon precursor compound represented by the following Formula 15 or Formula 18.

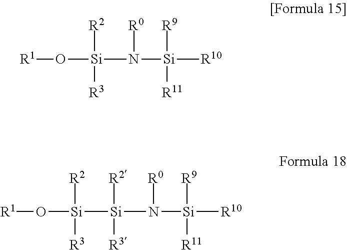

In Formula 15 or Formula 18, R¹ is any one selected from a linear or branched, saturated or unsaturated hydrocarbon group having 1 to 4 carbon atoms, an isomer thereof, and NR⁷R⁸; R², R^{2′}, R³, and R^{3′} are each any one selected from hydrogen (H), chlorine (Cl), methyl (Me), methoxy (MeO), ethoxy (EtO), n-propoxy, isopropoxy (^{iso}PrO), n-butoxy, isobutoxy (^{iso}BuO), sec-butoxy (^{sec} BuO), tert-butoxy (^{tert}BuO), and NR⁷R⁸; R⁰ is a linear or branched, saturated or unsaturated hydrocarbon group or an isomer thereof; R⁹, R¹⁰, and R¹¹ are each any one selected from hydrogen (H), chlorine (Cl), a methyl group (Me), an ethyl group (CH₂CH₃), and a vinyl group (CH═CH₂); and R⁷ and R⁸ in NR⁷R⁸ are each any one selected from methyl (Me), ethyl (Et), and iso-propyl (^{iso}Pr).

The silicon precursor compound of Formula 1 prepared according to the method for preparing a silicon precursor compound of the present invention is at least one selected from compounds (1) to (56).

In order to accomplish another object, the method for preparing a silicon-containing thin film according to the present invention may form a silicon-containing thin film using the silicon precursor compound represented by Formula 1.

In the method for preparing a silicon-containing thin film according to the present invention, the silicon precursor compound is at least one selected from compounds (1) to (56).

In the method for preparing a silicon-containing thin film according to the present invention, the silicon-containing thin film may be deposited by chemical vapor deposition (CVD), plasma-enhanced chemical vapor deposition (PECVD), or atomic layer deposition (ALD).

### Advantageous Effects of Invention

The silicon precursor compound of the present invention exhibits sufficient volatility to be applied to all of atomic layer deposition (ALD), plasma-enhanced chemical vapor deposition (PECVD), and chemical vapor deposition (CVD) for preparing silicon-containing thin films. In particular, deposition is possible even at high temperatures in a high deposition rate, whereby a silicon-containing thin film with excellent quality can be prepared.

However, the effects of the present invention are not limited to those mentioned above.

### BRIEF DESCRIPTION OF DRAWINGS

FIG. 1 shows a hydrogen nuclear magnetic resonance (¹H-NMR) spectrum of the silicon precursor compound prepared according to Example 1 of the present invention.

FIG. 2 shows a hydrogen nuclear magnetic resonance (¹H-NMR) spectrum of the silicon precursor compound prepared according to Example 2 of the present invention.

FIG. 3 shows a hydrogen nuclear magnetic resonance (¹H-NMR) spectrum of the silicon precursor compound prepared according to Example 3 of the present invention.

FIG. 4 shows a hydrogen nuclear magnetic resonance (¹H-NMR) spectrum of the silicon precursor compound prepared according to Example 4 of the present invention.

FIG. 5 shows a hydrogen nuclear magnetic resonance (¹H-NMR) spectrum of the silicon precursor compound prepared according to Example 5 of the present invention.

FIG. 6 shows a hydrogen nuclear magnetic resonance (¹H-NMR) spectrum of the silicon precursor compound prepared according to Example 6 of the present invention.

FIG. 7 is a graph showing the results of thermogravimetric analysis (TGA) of the silicon precursor compounds prepared according to the Examples of the present invention.

FIG. 8 is a graph showing the results of measuring the vapor pressure of the silicon precursor compounds prepared according to Examples 2, 3, 5, and 6 of the present invention.

FIG. 9 is a graph showing the order of each pulse in the deposition process of a silicon oxide thin film.

FIG. 10 is a result of AES (Auger Electron Spectroscopy) analysis of the composition of a silicon oxide thin film deposited according to the present invention.

FIGS. 11 to 13 are images of silicon oxide thin films deposited according to the present invention observed using a transmission electron microscope (TEM).

### BEST MODE FOR CARRYING OUT THE INVENTION

Hereinafter, the silicon precursor compound and the method for preparing the same according to the present invention will be described in detail.

In the present specification, the term “about” is intended to cover ±5% of the number defined.

The silicon precursor compound in an asymmetric structure containing an alkoxide according to the present invention may be represented by the following Formula 1.

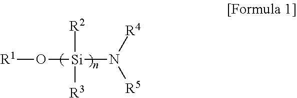

In Formula 1, n is 1 or 2; R¹ is any one selected from a linear or branched, saturated or unsaturated hydrocarbon group having 1 to 4 carbon atoms, an isomer thereof, and NR⁷R⁸; R² and R³ are each any one selected from hydrogen (H), chlorine (Cl), methyl (Me), methoxy (MeO), ethoxy (EtO), n-propoxy, isopropoxy (^{iso}PrO), n-butoxy, isobutoxy (^{iso}BuO), sec-butoxy (^{sec}BuO) tert-butoxy (^{tert}BuO), and NR⁷R⁸; R⁴ is a linear or branched, saturated or unsaturated hydrocarbon group (e.g., having 1 to 6 carbon atoms) or an isomer thereof; and R⁵ is any one selected from methyl (Me), ethyl (Et), iso-propyl ('s° Pr), SiMe₃, SiHMe₂, SiH₂Me, SiH₃, SiHClMe, SiHCl₂, SiMe₂CH₂CH₃, SiMe₂CH═CH₂, and SiHMeCH═CH₂.

R⁷ and R⁸ in NR⁷R⁸ are each any one selected from methyl (Me), ethyl (Et), and iso-propyl (^{iso}Pr).

The hydrocarbon groups in R¹ and R⁴ may each independently be any one selected from the group consisting of a methyl group (Me), an ethyl group (Et), an n-propyl group (Pr), an iso-propyl group (^{iso}Pr), an n-butyl group (Bu), a sec-butyl group (^{sec}Bu), an iso-butyl group (^{iso}Bu), a tert-butyl group (^{tert}Bu), and isomers thereof.

In the present invention, R⁴ and R⁵ may be different from each other, preferably, R⁴ and R⁵ are different from each other.

The alkoxide in the present invention is a compound in which hydrogen (H) in a hydroxyl group (OH) of an alcohol is substituted with a metal. It is a silicon alkoxide in which silicon (Si) is substituted as a metal.

The silicon precursor compound of the present invention may be prepared by a method as shown in Reaction Scheme 1 and Reaction Scheme 2 below.

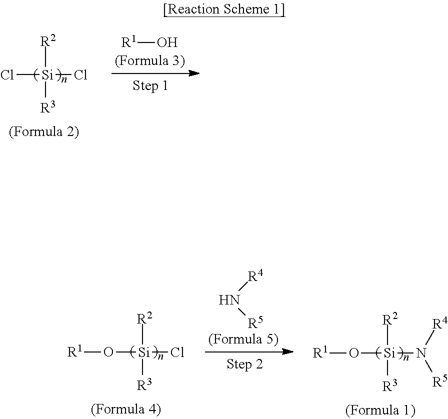

In the method for preparing a silicon precursor according to Reaction Scheme 1, an alkoxide compound is reacted with a secondary amine to prepare a silicon precursor compound represented by Formula 1. It is carried out by a first step of reacting a chlorosilane compound represented by Formula 2 with an alcohol compound represented by Formula 3 to form an alkoxide compound; and a second step of reacting the alkoxide compound with a secondary amine represented by Formula 5 to prepare a silicon precursor compound represented by Formula 1.

As a specific example of Reaction Scheme 1, when n is 1, and R² is hydrogen (H), a silicon compound represented by Formula 8 can be prepared as shown in Reaction Scheme 2 below.

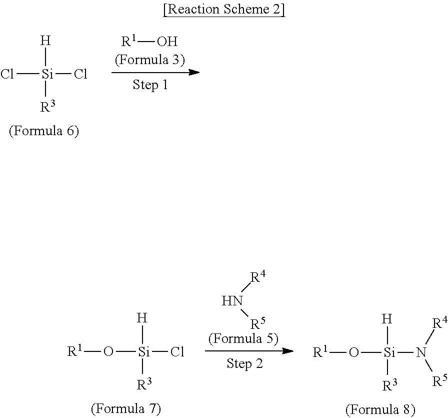

In Reaction Schemes 1 and 2, n is 1 or 2; R¹ is any one selected from a linear or branched, saturated or unsaturated hydrocarbon group having 1 to 4 carbon atoms, an isomer thereof, and NR⁷R⁸; R² and R³ are each any one selected from hydrogen (H), chlorine (Cl), methyl (Me), methoxy (MeO), ethoxy (EtO), n-propoxy, isopropoxy (^{iso}PrO), n-butoxy, isobutoxy (^{iso}BuO), sec-butoxy (^{sec}BuO), tert-butoxy (^{tert}BuO), and NR⁷R⁸; R⁴ is a linear or branched, saturated or unsaturated hydrocarbon group (e.g., having 1 to 6 carbon atoms) or an isomer thereof; and R⁵ is any one selected from methyl (Me), ethyl (Et), iso-propyl (^{iso}Pr), SiMe₃, SiHMe₂, SiH₂Me, SiH₃, SiHClMe, SiHCl₂, SiMe₂CH₂CH₃, SiMe₂CH═CH₂, and SiHMeCH═CH₂.

In the method for preparing a silicon precursor according to Reaction Schemes 1 and 2, in the first step, a chlorosilane compound is reacted with an alcohol compound at a low temperature of about −40° C. in a non-polar solvent to perform a substitution reaction of Cl and an alcohol compound, followed by filtration and distillation under a reduced pressure to form an alkoxide compound.

In the second step, the alkoxide compound formed in the first step is reacted with a secondary amine represented by Formula 5, followed by the removal of a product salt and unreacted materials of the reactants through filtration and distillation under a reduced pressure to obtain a silicon precursor compound.

The silicon precursor compound of the present invention may be prepared by another method as shown in Reaction Scheme 3 and Reaction Scheme 4 below.

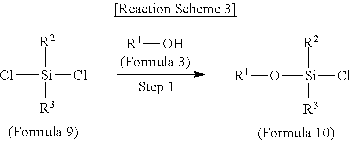

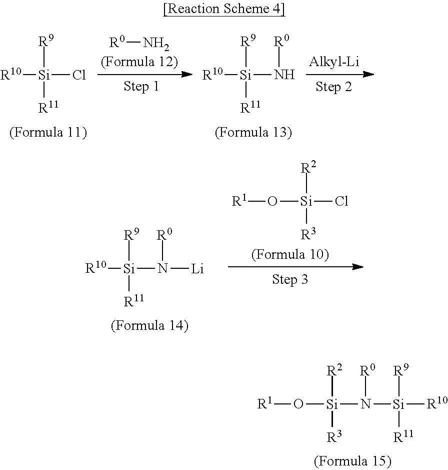

In the method for preparing a silicon precursor according to Reaction Schemes 3 and 4, an alkoxide compound is reacted with an alkylaminosilane to prepare a silicon precursor compound.

As shown in Reaction Scheme 4, it is carried out by a first step of reacting a chlorosilane compound represented by Formula 11 with a primary amine represented by Formula 12 to form an alkylaminosilane represented by Formula 13; a second step of reacting the alkylaminosilane with an alkyl-lithium (Alkyl-Li) to form an alkylaminosilane containing lithium as represented by Formula 14; and a third step of reacting the compound of Formula 14 with an alkoxide compound of Formula 10 to prepare a silicon precursor compound represented by Formula 15.

The alkoxide compound represented by Formula 10 may be formed by reacting a chlorosilane compound represented by Formula 9 with an alcohol compound represented by Formula 3 as shown in Reaction Scheme 3.

Another method for preparing a silicon precursor compound is carried out in the same manner as in Reaction Scheme 4, except that the alkoxide compound used in Reaction Scheme 4 is a compound of Formula 17 prepared according to Reaction Scheme 5 below to prepare a silicon precursor compound of Formula 18 as shown in Reaction Scheme 6.

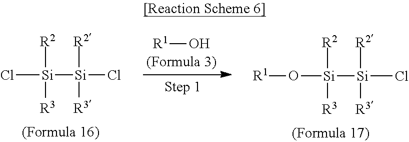

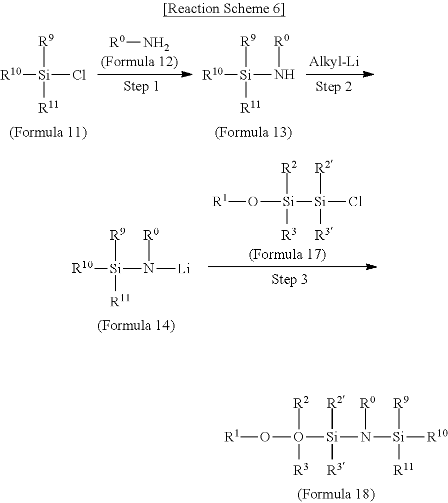

In Reaction Schemes 3 to 6, R¹ is any one selected from a linear or branched, saturated or unsaturated hydrocarbon group having 1 to 4 carbon atoms, an isomer thereof, and NR⁷R⁸; R², R^{2′}, R³, and R^{3′} are each any one selected from hydrogen (H), chlorine (Cl), methyl (Me), methoxy (MeO), ethoxy (EtO), n-propoxy, isopropoxy (^{iso}PrO), n-butoxy, isobutoxy (^{iso} BuO), sec-butoxy (^{sec} BuO), tert-butoxy (^{tert}BuO), and NR⁷R⁸; R⁰ is a linear or branched, saturated or unsaturated hydrocarbon group (e.g., having 1 to 6 carbon atoms) or an isomer thereof; and R⁹, R¹⁰, and R¹¹ are each any one selected from hydrogen (H), chlorine (Cl), a methyl group (Me), an ethyl group (CH₂CH₃), and a vinyl group (CH═CH₂).

In the method for preparing a silicon precursor according to Reaction Schemes 4 and 6, in the first step, a triorganochlorosilane as a chlorosilane compound is reacted with a primary amine at a low temperature of about −40° C. in a non-polar solvent to perform a substitution reaction of Cl and an amine, followed by filtration and distillation under a reduced pressure to form an alkylaminosilane of Formula 13.

In the second step, the alkylaminosilane formed in the first step is reacted with an alkyl-lithium (alkyl-Li) at a low temperature of about −40° C. in a non-polar solvent to perform a Li substitution reaction to form a compound of Formula 14.

Here, the alkyl-Li is lithium containing an alkyl group having 1 to 10 carbon atoms. Examples thereof include methyl lithium, ethyl lithium, propyl lithium, butyl lithium, and isobutyl lithium.

In the third step, after a reaction with the alkoxide compound represented by Formula 10 or 17, the salt (LiCl) as a product of the reaction and unreacted materials are removed through filtration, and distillation under a reduced pressure is performed to obtain a silicon precursor compound.

As the non-polar solvent used in Reaction Schemes 1 to 6, hexane, n-pentane, or the like may be used, but it is not limited thereto. A non-polar solvent commonly used by a person of ordinary skill in the art can be used.

The silicon precursor compound of the present invention may be selected from the group consisting of the following compounds (1) to (56).

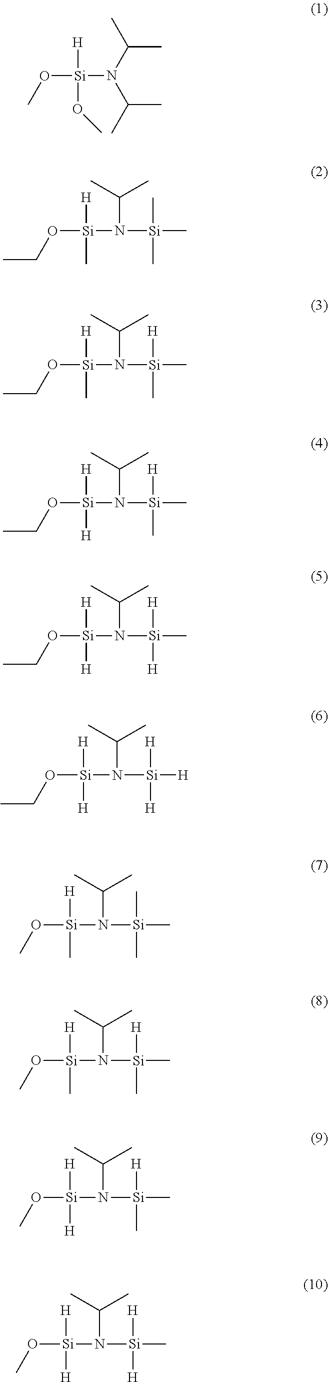

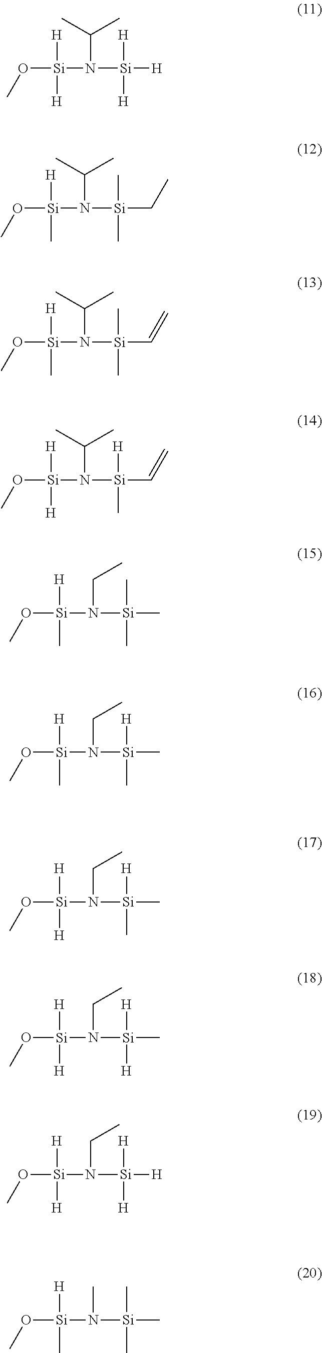

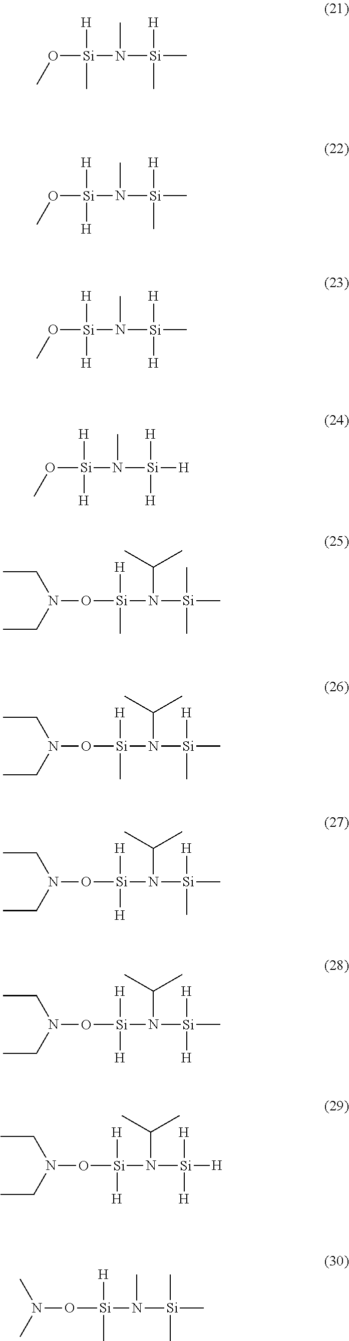

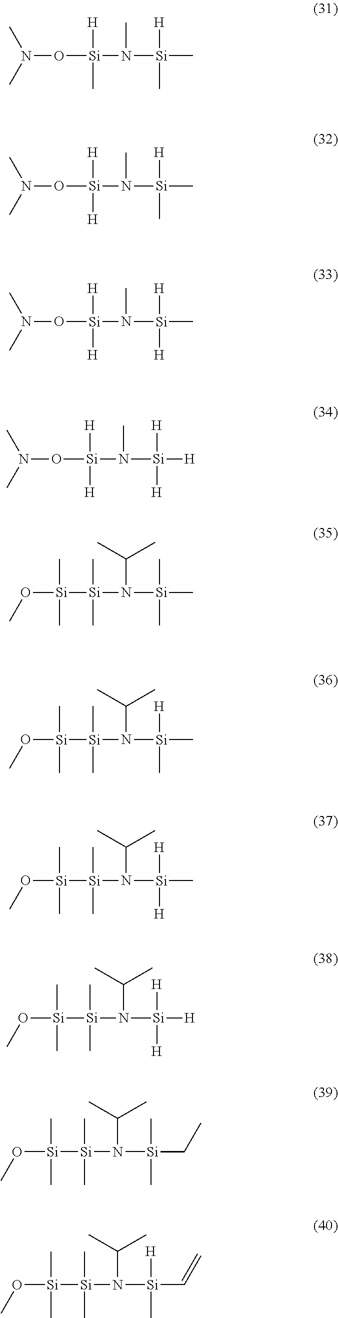

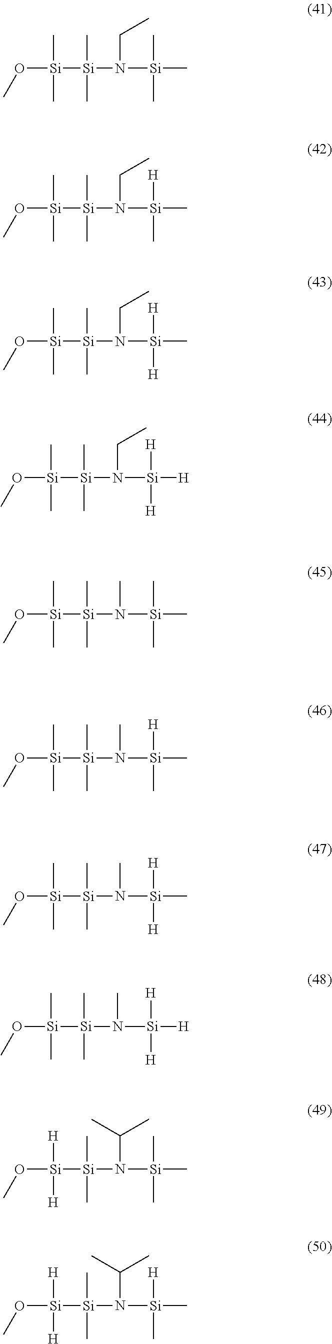

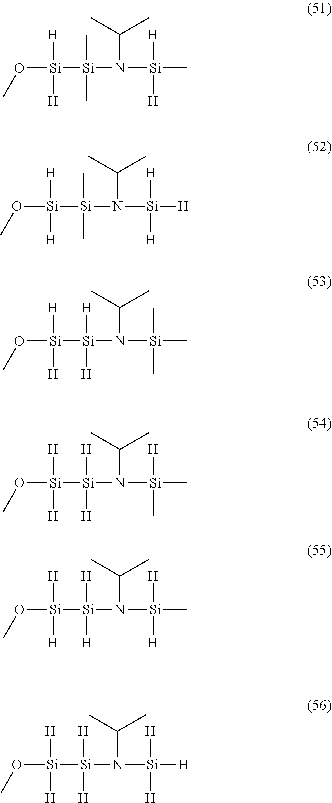

In addition, according to the method for preparing a silicon-containing thin film of the present invention, a silicon-containing thin film can be formed using the silicon precursor compound represented by Formula 1 by chemical vapor deposition (CVD), plasma-enhanced chemical vapor deposition (PECVD), or atomic layer deposition (ALD) well known to a person of ordinary skill in the art. The silicon-containing thin film according to the present invention may be any one selected from the group consisting of a silicon oxide (SiO₂) film, a silicon oxycarbide (SiOC) film, a silicon nitride (SiN) film, a silicon oxynitride (SiON) film, a silicon carbonitride (SiCN) film, a silicon oxycarbonitride (SiOCN) film, and silicon carbonized (SiC) film, but it is not limited thereto. The silicon-containing thin film according to the present invention is preferably a silicon oxide film (SiO₂).

The silicon oxide film according to the present invention is preferably deposited by atomic layer deposition. The atomic layer deposition comprises providing a substrate to a reactor; feeding a silicon precursor compound to the reactor; purging the reactor with a purge gas; feeding an oxygen source to the reactor to react with the silicon precursor compound to form a silicon oxide film; and purging the reactor with a purge gas. The purge gas is selected from the group consisting of nitrogen, helium, argon, and mixtures thereof, but it is not limited thereto. The oxygen source is selected from the group consisting of oxygen, peroxide, oxygen plasma, water vapor, water vapor plasma, hydrogen peroxide, ozone source, and mixtures thereof, but it is not limited thereto. The oxygen source is preferably ozone (O₃).

The step of forming the silicon oxide film may be carried out at a temperature of about 200° C. to about 600° C. and is preferably carried out at a temperature of about 400° C.

Hereinafter, the present invention will be described in detail with reference to examples.

### Example 1

In Example 1, diisopropyldimethoxysilaneamine of compound (1) was prepared as a silicon precursor compound.

In the first step, dichlorodiisopropylsilanamine (1,1-dichloro-N,N-diisopropylsilanamine) was prepared. A 5-liter flask in an anhydrous and inert atmosphere was charged with 200 g (1.48 moles) of trichlorosilane (HSiCl₃) and 1,279 g (17.72 moles) of n-pentane. While the temperature was maintained at −40° C., 306 g (3.03 moles) of diisopropylamine (((CH₃)₂CH)₂NH) was slowly added, followed by stirring for 3 hours. Upon completion of the stirring, the diisopropylamine hydrochloride salt (((CH₃)₂CH)₂NH₂Cl) was removed through filtration, and 264.5 g (1.48 moles) of dichlorodiisopropylsilaneamine (((CH₃)₂CH)₂NSiHCl₂) (yield: 89%) was obtained through purification under a reduced pressure.

¹H-NMR (C₆D₆): δ 0.92(d, 12H(N(CH(CH₃)₂)₂)), 3.09(m, 2H(N(CH(CH₃)₂)₂)), 5.65 (s, 1H(—SiH))

In the second step, a 5-liter flask in an anhydrous and inert atmosphere was charged with 161 g (1.11 moles) of dichlorodiisopropylsilaneamine (((CH₃)₂CH)₂NSiHCl₂) prepared in the first step and 1,430 g (19.82 moles) of n-pentane. While the temperature was maintained at −40° C., 274 g (2.71 moles) of triethylamine (N(CH₂CH₃)₃) was slowly added, and 109 ml (2.71 moles) of methanol (CH₃OH) was slowly added. The temperature was then gradually raised to room temperature, followed by stirring for 3 hours. Upon completion of the stirring, the triethylamine salt (N(CH₂CH₃)₃HCl) was removed through filtration, followed by removing the solvent under a reduced pressure and distillation to obtain 156.8 g (1.32 moles) of diisopropyldimethoxysilaneamine (((CH₃)₂CH)₂NSiH(OCH₃)₂) (yield: 62.3%) as a silicon precursor compound.

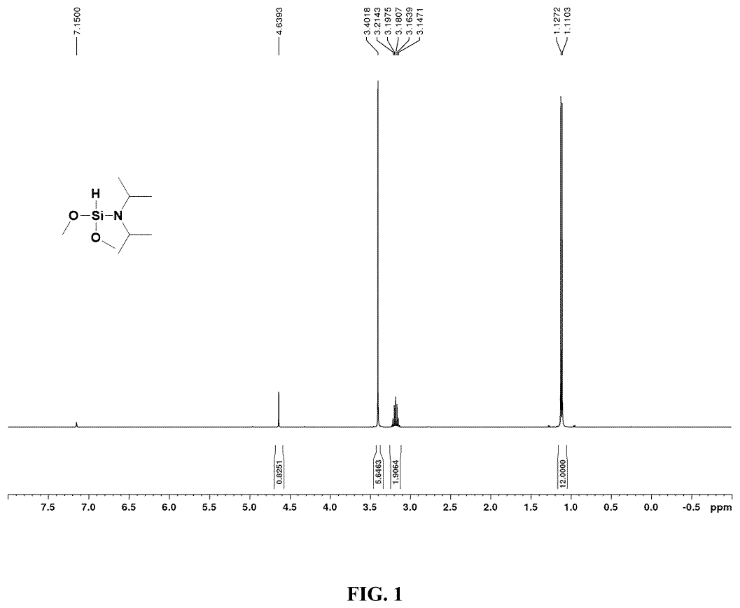

FIG. 1 shows a hydrogen nuclear magnetic resonance (¹H-NMR) spectrum of the silicon precursor compound prepared according to Example 1 of the present invention. As shown, the silicon precursor compound prepared in Example 1 was confirmed to be diisopropyldimethoxysilaneamine.

¹H-NMR (C₆D₆): δ 1.11(d, 12H(N(CH(CH₃)₂)₂)), 3.18(m, 2H(N(CH(CH₃)₂)₂)), 3.40 (s, 6H(OCH₃)₂), 4.63 (s, 1H(—SiH))

### Example 2

In Example 2, ethoxymethylsilylisopropyltrimethylsilanamine of compound (2) was prepared as a silicon precursor compound.

First, chloro(ethoxy)(methyl)silane as a silane compound needed to prepare a silicon precursor compound was prepared. A 1-liter flask in an anhydrous and inert atmosphere was charged with 250 g (2.17 moles) of dichloromethylsilane (CH₃SiHCl₂) and 1,568 g (21.73 mol) of n-pentane. While the temperature was maintained at −40° C., 230 g (2.28 moles) of triethylamine (N(CH₂CH₃)₃) was slowly added, and, in one hour, ethanol (CH₃CH₂OH) was slowly added. The temperature of the reaction solution was then gradually raised to room temperature, followed by stirring for 3 hours. Upon completion of the stirring, the triethylamine hydrochloride salt (N(CH₂CH₃)₃HCl) was removed through filtration, and 185 g (1.49 moles) of chloroethoxymethylsilane (CH₃CH₂OSiHMeCl) (yield: 69%) was obtained through purification under a reduced pressure.

¹H-NMR (C₆D₆): δ 0.22(d, 3H(—SiCH₃)), 1.01(t, 3H(—OCH₂CH₃)), 3.59(m, 2H(—OCH₂CH₃)), 5.14(m, 1H(—SiH))

In the first step of Example 2, isopropylaminotrimethylsilazane was prepared. A 1-liter flask in an anhydrous and inert atmosphere was charged with 220 g (2.03 moles) of chlorotrimethylsilane ((CH₃)₃SiCl) and 2,190 g (30 moles) of n-pentane. While the temperature was maintained at −40° C., 251 g (4.25 moles) of isopropylamine ((CH₃)₂CHNH₂) was slowly added, followed by stirring for 3 hours. Upon completion of the stirring, the isopropylamine hydrochloride salt ((CH₃)₂CHNH₃Cl) was removed through filtration, followed by removing the solvent under a reduced pressure and distillation to obtain 205 g (1.5 moles) of isopropylaminotrimethylsilazane ((CH₃)₂CHNSiH(CH₃)₃) (yield: 77%).

¹H-NMR (C₆D₆): δ 0.06(s, 9H(SiCH₃)₃), 0.96(d, 6H(NCH(CH₃)₂)), 2.92(m, 1H(NCH(CH₃)₂))

In the second step of Example 2, a 1-liter flask in an anhydrous and inert atmosphere was charged with 200 g (1.38 moles) of isopropylaminotrimethylsilazane ((CH₃)₂CHNSiH(CH₃)₃) prepared in the first step and 1,186 g (13.76 moles) of hexane. While the temperature was maintained at −40° C., 402 ml (1.45 moles) of 2.5 M n-butyllithium (n-BuLi) was slowly added. The temperature was then gradually raised to room temperature, followed by stirring for 12 hours.

Next, in the third step of Example 2, while the mixed solution in the second step was maintained at −20° C., 171.5 g (1.38 moles) of chloroethoxymethylsilane (CH₃CH₂OSiHMeCl) was slowly added thereto, followed by stirring for 6 hours or longer. Upon completion of the stirring, the lithium chloride (LiCl) salt was removed through filtration. The solvent in the filtrate was removed under a reduced pressure, followed by distillation to obtain 181 g (1.38 moles) of ethoxymethylsilylisopropyltrimethylsilanamine (CH₃CH₂OSiHMeNiPrSiMe3) (yield: 60%) as a silicon precursor compound.

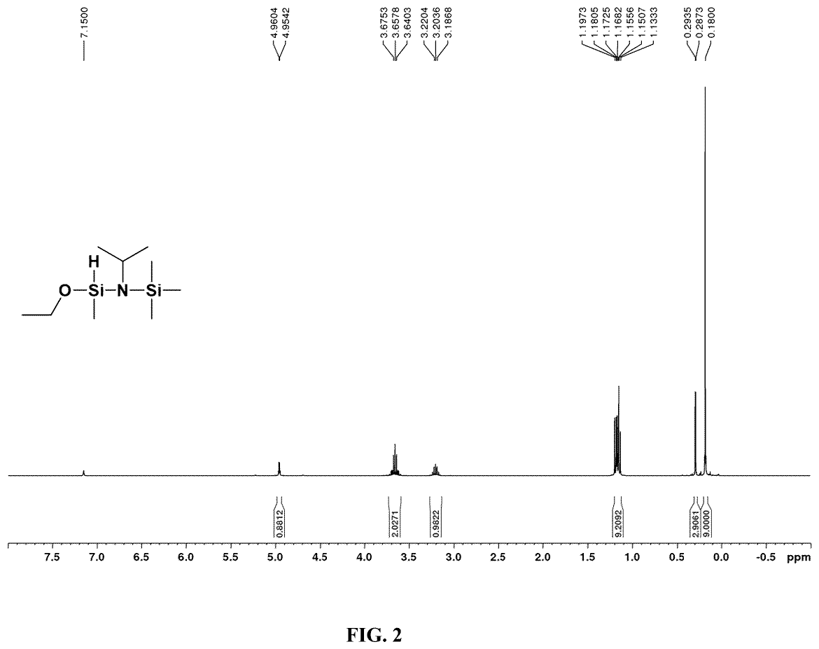

FIG. 2 shows a hydrogen nuclear magnetic resonance (¹H-NMR) spectrum of the silicon precursor compound prepared according to Example 2 of the present invention. As shown, the silicon precursor compound prepared in Example 2 was confirmed to be ethoxymethylsilylisopropyltrimethylsilanamine.

¹H-NMR (C₆D₆): δ 0.18(s, 9H(—Si(CH₃)₃)), 0.28(d, 3H(—SiHCH₃)), 1.15(t, 3H(—O(CH₂CH₃))), 1.17(m, 6H(—SiNCH(CH₃)₂)), 3.20(m, 1H(—NCH(CH₃)₂)), 3.65(m, 2H(—O(CH₂CH₃))), 4.95(m, 1H(—SiH))

### Example 3

In Example 3, dimethylsilylethoxyisopropylmethylsilanamine of compound (3) was prepared as a silicon precursor compound.

In the first step of Example 3, isopropyldimethylsilaneamine was prepared. A 1-liter flask in an anhydrous and inert atmosphere was charged with 100 g (1.06 moles) of chlorodimethylsilane ((CH₃)₂SiHCl) and 1,143 g (15.0 moles) of n-pentane. While the temperature was maintained at −40° C., 128 g (2.17 moles) of isopropylamine ((CH₃)₂CHNH₂) was slowly added, followed by stirring for 3 hours. Upon completion of the stirring, the isopropylamine hydrochloride salt ((CH₃)₂CHNH₃Cl) was removed through filtration, followed by purification under a reduced pressure to obtain 101 g (1.06 moles) of isopropyldimethylsilaneamine ((CH₃)₂CHNHSiH(CH₃)₂) (yield: 82%).

¹H-NMR (C₆D₆): δ 0.08(s, 6H(Si(CH₃)₂)), 0.96(d, 6H(NCH(CH₃)₂)), 2.95(m, 1H (NCH(CH₃)₂)), 4.71(m, 1H(—SiH))

In the second step of Example 3, a 1-liter flask in an anhydrous and inert atmosphere was charged with 100 g (0.85 mole) of isopropyldimethylsilaneamine ((CH₃)₂CHNHSiH(CH₃)₂) prepared in the first step and 367 g (5.0 moles) of hexane. While the temperature was maintained at −40° C., 257 ml (0.90 mole) of 2.5 M n-butyllithium (n-BuLi) was slowly added. The temperature was then gradually raised to room temperature, followed by stirring for 12 hours.

Next, in the third step of Example 3, while the mixed solution in the second step was maintained at −20° C., 177 g (0.85 mole) of chloroethoxymethylsilane (CH₃CH₂OSiHMeCl) was slowly added thereto, followed by stirring for 6 hours or longer. Upon completion of the stirring, the lithium chloride (LiCl) salt was removed through filtration. The solvent in the filtrate was removed under a reduced pressure, followed by distillation to obtain 122 g of dimethylsilylethoxyisopropylmethylsilanamine (CH₃CH₂OSiHMeNiPrSiHMe2) (yield: 70%) as a silicon precursor compound.

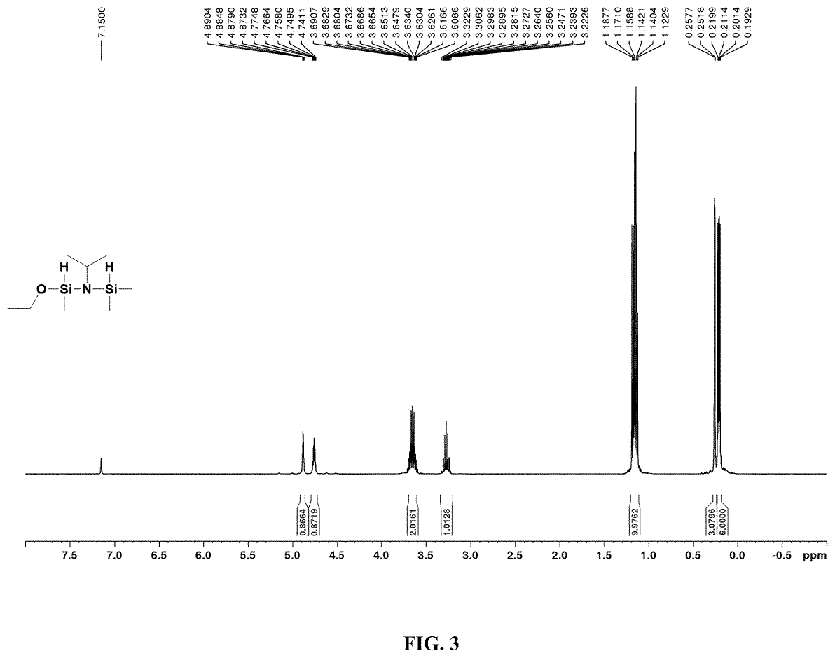

FIG. 3 shows a hydrogen nuclear magnetic resonance (¹H-NMR) spectrum of the silicon precursor compound prepared according to Example 3 of the present invention. As shown, the silicon precursor compound prepared in Example 3 was confirmed to be dimethylsilylethoxyisopropylmethylsilanamine.

¹H-NMR (C₆D₆): δ 0.20(m, 6H(—SiH(CH₃)₂)), 1.14(t, 3H(—O(CH₂CH₃)), 1.17(m, 6H(—SiNCH₂(CH₃)₂)), 3.27(m, 1H(NCH(CH₃)₂)), 3.65(m, 2H(—O(CH₂CH₃))), 4.75(m, 1H(—SiH(CH₃)₂)), 4.88(m, 1H(—SiH(CH₃)₂))

### Example 4

In Example 4, diethylaminooxymethylsilylisopropyltrimethylsilanamine of compound (25) was prepared as a silicon precursor compound.

In the first step of Example 4, isopropylaminotrimethylsilazane was prepared in the same manner as in Example 2.

In the second step of Example 4, chloro(methyl)silyl)diethylhydroxylamine was prepared. A 1-liter flask in an anhydrous and inert atmosphere was charged with 100 g (0.86 mole) of dichloromethylsilane (CH₃SiHCl₂) and 1,140 g (13.04 moles) of n-pentane. While the temperature was maintained at −40° C., 92.4 g (0.92 mole) of triethylamine ((CH₃CH₂)₃N) was added, and, in one hour, 81.4 g (0.92 mole) of diethylhydroxyamine ((CH₃CH₂)₂NOH) was slowly added. The temperature was then raised to room temperature, followed by stirring for 3 hours. Upon completion of the stirring, the triethylamine hydrochloride salt ((CH₃CH₂)₃NHCl) was removed through filtration, followed by removing the solvent under a reduced pressure and distillation to obtain 132 g (0.78 mole) of chloro(methyl)silyl)diethylhydroxylamine ((CH₃CH₂)₂NOSiHMeCl) (yield: 90%).

¹H-NMR (C₆D₆): δ 0.34(d, 3H(SiCH₃)), 0.83(m, 6H—ON(CH₂CH₃)₂), 2.66(m, 4H(—ON(CH₂CH₃)₂), 5.23(m, 1H(—SiH))

In the third step of Example 4, a 1-liter flask in an anhydrous and inert atmosphere was charged with 14 g (0.12 mole) of isopropylaminotrimethylsilazane ((CH₃)₂CHNHSi(CH₃)₃) prepared in the first step and 74.2 g (0.86 mole) of hexane. While the temperature was maintained at −40° C., 52 ml (0.13 mole) of 2.5 M n-butyllithium (n-BuLi) was slowly added. The temperature was then gradually raised to room temperature, followed by stirring for 2 hours. Next, while the mixed solution was maintained at −20° C., 30 g (0.12 mole) of chloro(methyl)silyl)diethylhydroxylamine ((CH₃CH₂)₂NOHSiCH₃Cl) prepared in the second step was slowly added thereto, followed by stirring for 6 hours at room temperature. Upon completion of the stirring, the lithium chloride (LiCl) salt was removed through filtration. The solvent in the filtrate was removed under a reduced pressure, followed by purification to obtain g of diethylaminooxymethylsilylisopropyltrimethylsilanamine ((CH₃CH₂)₂NOCH₃HSiNCH(CH₃)₂Si(CH₃)₃) (yield: 62%) as a silicon precursor compound.

¹H-NMR (C₆D₆): δ 0.12(s, 9H(—Si(CH₃)₃), 0.25(d, 3H(—SiHCH₃)), 1.07(m, 6H(—ON(CH₂CH₃) 2), 1.20(m, 6H(—NCH(CH₃)₂)), 2.76(m, 4H(—ON(CH₂CH₃)₂)), 3.29(m, 1H(—NCH(CH₃)₂)), 4.69(m, 1H(—SiH))

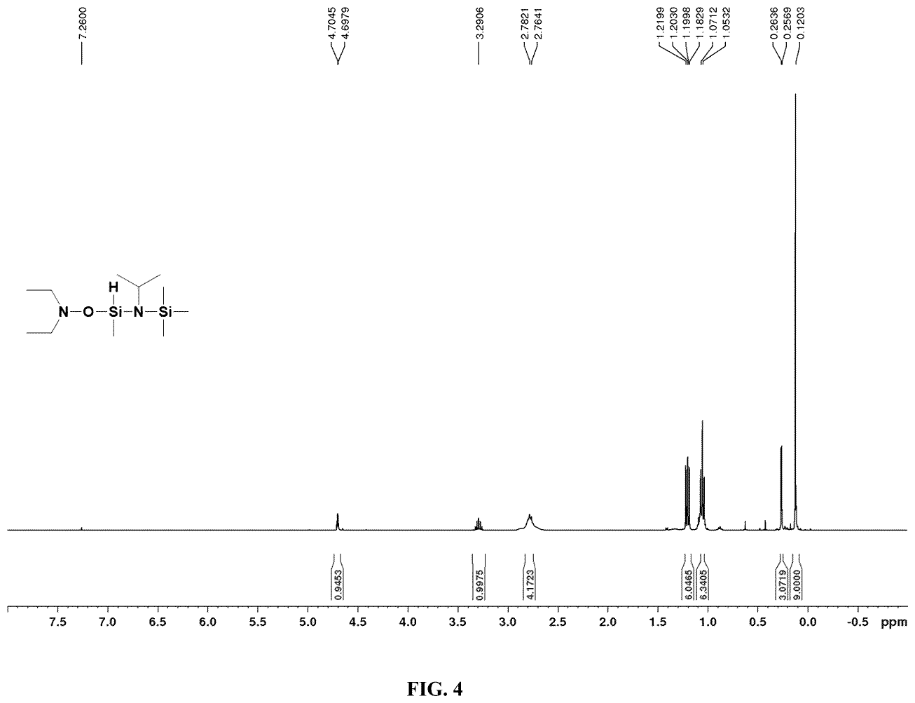

FIG. 4 shows a hydrogen nuclear magnetic resonance (¹H-NMR) spectrum of the silicon precursor compound prepared according to Example 4 of the present invention. As shown, the silicon precursor compound prepared in Example 4 was confirmed to be diethylaminooxymethylsilylisopropyltrimethylsilanamine.

### Example 5

In Example 5, isopropylmethoxytetramethyltrimethylsilyldisilanamine of compound (35) was prepared as a silicon precursor compound.

In the first step of Example 5, chloromethoxytetramethyldisilane was prepared. A 1-liter flask in an anhydrous and inert atmosphere was charged with 193 g (1.03 moles) of dichlorotetramethyldisilane (Cl(CH₃)₂SiSi(CH₃)₂Cl) and 2,754 g (38.15 moles) of n-pentane. While the temperature was maintained at −40° C., 99 g (0.98 mole) of triethylamine (N(CH₂CH₃)₃) was slowly added, and 31 g (0.98 mole) of methanol (HOCH₃) was slowly added. The temperature was then gradually raised to room temperature, followed by stirring for 16 hours. Upon completion of the stirring, the triethylamine salt (N(CH₂CH₃)₃HCl) was removed through filtration, followed by removing the solvent under a reduced pressure and distillation to obtain 119 g (0.65 mole) of chloromethoxytetramethyldisilane (CH₃O(CH₃)₂SiSi(CH₃)₂Cl) (yield: 67%).

¹H-NMR (CDCl₃): δ 0.32(s, 6H(—Si(OCH₃)(CH₃)₂)), 0.53(s, 6H(—SiCl(CH₃)₂)), 3.48(s, 3H(—OCH₃))

In the second step of Example 5, a 1-liter flask in an anhydrous and inert atmosphere was charged with 129 g (0.89 mole) of isopropyltrimethylsilanamine ((CH₃)₂CHNHSi(CH₃)₃) and 535 g (6.20 moles) of n-hexane. While the temperature was maintained at −15° C., 372 ml (0.93 mole) of 2.5 M n-butyllithium (n-BuLi) was slowly added. The temperature was then gradually raised to room temperature, followed by stirring for 2 hours.

Next, in the third step of Example 5, while the mixed solution in the second step was maintained at −3° C., 162 g (0.89 mole) of chloromethoxytetramethyldisilane (CH₃O(CH₃)₂SiSi(CH₃)₂Cl) prepared in the first step was slowly added thereto, followed by raising the temperature to room temperature and stirring for 16 hours. Upon completion of the stirring, the lithium chloride (LiCl) salt was removed through filtration. The solvent in the filtrate was removed under a reduced pressure, followed by distillation to obtain 138 g (0.48 mole) of isopropylmethoxytetramethyltrimethylsilyldisilanamine (CH₃O(CH₃)₂SiSi(CH₃)₂N(CH(CH₃)₂)Si(CH₃)₃) (yield: 54%) as a silicon precursor compound.

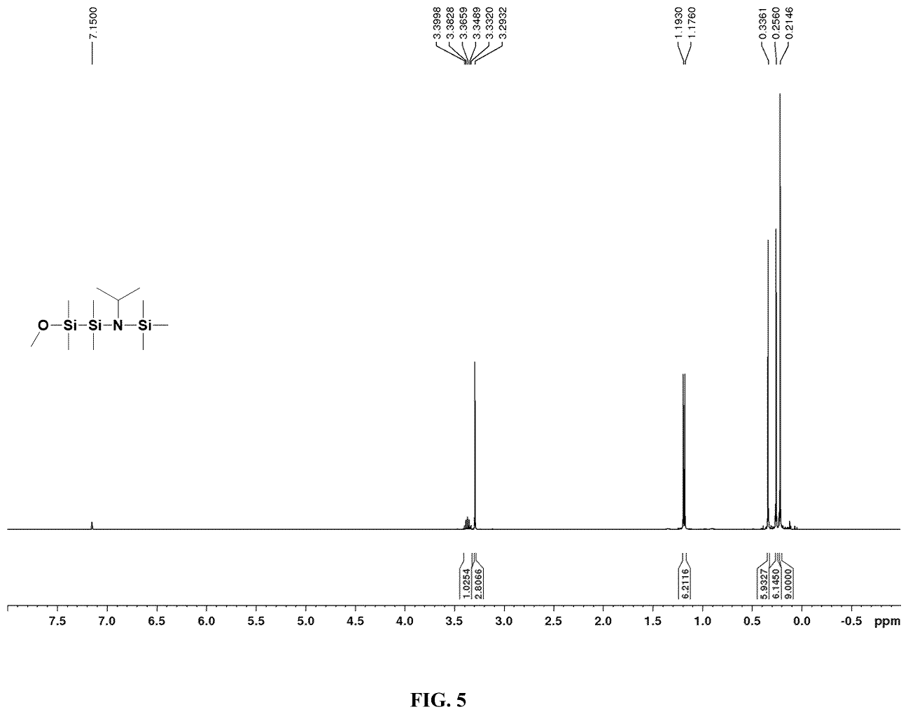

FIG. 5 shows a hydrogen nuclear magnetic resonance (¹H-NMR) spectrum of the silicon precursor compound prepared according to Example 5 of the present invention. As shown, the silicon precursor compound prepared in Example 5 was confirmed to be isopropylmethoxytetramethyltrimethylsilyldisilanamine.

¹H-NMR (C₆D₆): δ 0.21(s, 9H(—Si(CH₃)₃)), 0.26(s, 6H(—Si(CH₃)₂N—)), 0.34(s, 6H(CH₃OSi(CH₃)₂Si—)), 1.18(d, 6H(—NCH(CH₃)₂)), 3.29(s, 3H(CH₃O—)), 3.37(m, 1H(—NCH(CH₃)₂))

### Example 6

In Example 6, dimethylsilylisopropylmethoxytetramethyldisilanamine of compound (36) was prepared as a silicon precursor compound.

In the first step of Example 6, chloromethoxytetramethyldisilane was prepared in the same manner as in Example 5.

In the second step of Example 6, a 1-liter flask in an anhydrous and inert atmosphere was charged with 92 g (0.78 mole) of isopropyldimethylsilanamine ((CH₃)₂CHNHSiH(CH₃)₂) prepared in the first step of Example 3 and 472 g (5.48 moles) of n-hexane. While the temperature was maintained at −15° C., 328 ml (0.82 mole) of 2.5 M n-butyllithium (n-BuLi) was slowly added. The temperature was then gradually raised to room temperature, followed by stirring for 2 hours.

Next, in the third step of Example 6, while the mixed solution in the second step was maintained at −3° C., 162 g (0.89 mole) of chloromethoxytetramethyldisilane (CH₃O(CH₃)₂SiSi(CH₃)₂Cl) was slowly added thereto, followed by raising the temperature to room temperature and stirring for 16 hours. Upon completion of the stirring, the lithium chloride (LiCl) salt was removed through filtration. The solvent in the filtrate was removed under a reduced pressure, followed by distillation to obtain 108 g (0.41 mole) of dimethylsilylisopropylmethoxytetramethyldisilanamine (CH₃O(CH₃)₂SiSi(CH₃)₂N(CH(CH₃)₂)SiH(CH₃)₂) (yield: 52%) as a silicon precursor compound.

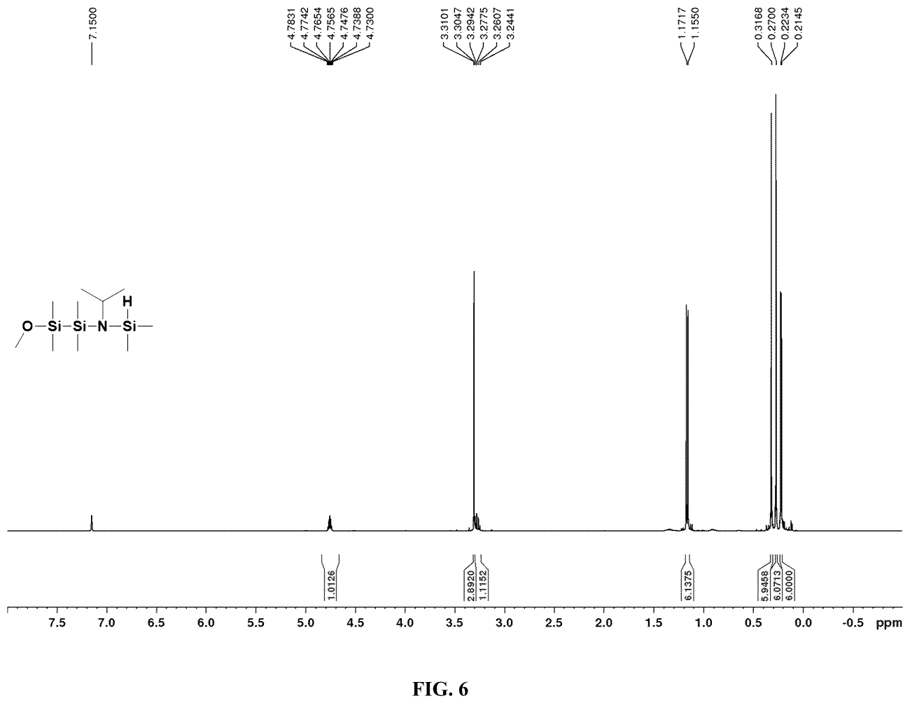

FIG. 6 shows a hydrogen nuclear magnetic resonance (¹H-NMR) spectrum of the silicon precursor compound prepared according to Example 6 of the present invention. As shown, the silicon precursor compound prepared in Example 6 was confirmed to be dimethylsilylisopropylmethoxytetramethyldisilanamine.

¹H-NMR (C₆D₆): δ 0.22(d, 6H(—SiH(CH₃)₂)), 0.27(s, 6H(—Si(CH₃)₂N—)), 0.32(s, 6H(CH₃OSi(CH₃)₂Si—)), 1.16(d, 6H(—NCH(CH₃)₂)), 3.28(m, 1H(—NCH(CH₃)₂)), 3.30(s, 3H(CH₃O—)), 4.76(m, 1H(—SiH(CH₃)₂))

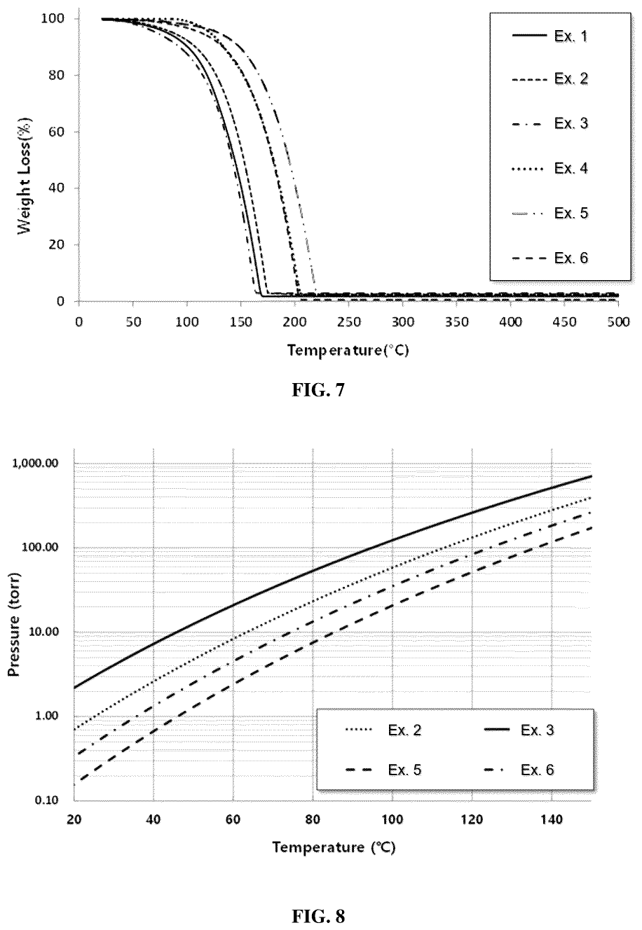

Thermogravimetric analysis (TGA) was carried out to analyze the thermal characteristics of the silicon precursor compounds prepared in Examples 1 to 6. The results are shown in FIG. 7.

As shown in FIG. 7, the silicon precursor compounds of Examples 4, 5, and 6 show volatility in various temperature ranges of 220° C. or lower, between 220° C. and 500° C., and 500° C. or higher. In particular, the silicon precursor compounds of Examples 1, 2, and 3 show volatility in the temperature ranges of 170° C. or lower, between 170° C. to 500° C., and 500° C. or higher, which are lower than the temperature ranges of the silicon precursor compounds of Examples 4, 5, and 6. Thus, they are an excellent silicon precursor capable of forming a silicon-containing thin film in a wide range of temperatures.

The above results show that all of the silicon precursor compounds prepared according to the Examples of the present invention show sufficient volatility to be applied to atomic layer deposition (ALD) or chemical vapor deposition (CVD).

In order to confirm that the silicon precursor compounds prepared according to Examples 2, 3, 5, and 6 had a vapor pressure suitable for the preparation of a silicon oxide thin film through a deposition method, their vapor pressures were measured. The results are shown in FIG. 8.

As shown in FIG. 8, all of the silicon precursor compounds of Examples 2, 3, 5, and 6 showed a high vapor pressure of 10 Torr or more at about 100° C. Among them, Example 3 showed a higher vapor pressure at a lower temperature than the other Examples.

The above vapor pressure results show that all of the silicon precursor compounds prepared according to the Examples of the present invention show a high vapor pressure of 10 Torr or more at a low temperature of about 100° C. or lower, indicating a sufficient vapor pressure to be applied to atomic layer deposition (ALD) or chemical vapor deposition (CVD).

### Preparation of Silicon-Containing Thin Films

Here, a silicon oxide thin film, SiO₂, is prepared and described as a representative example, but it is not limited thereto. Silicon-containing thin films known in the art such as SiN, SiO₂, and SiCN can be formed.

An experiment was carried out to form a silicon oxide thin film on a silicon substrate by using the silicon compound of Example 2, ethoxymethylsilylisopropyltrimethylsilanamine, as a precursor and using atomic layer deposition (ALD). An ALD reactor in which a precursor and a reactive gas (O₃) are separately supplied in a vertical direction using a double shower head was used.

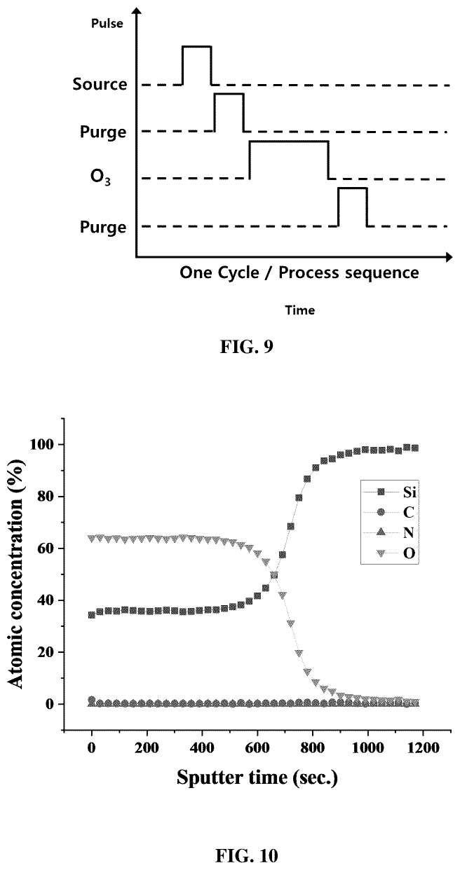

Table 1 and FIG. 9 show the specific conditions for silicon oxide thin film deposition.

TABLE 1

| | | | Precursor | Purge | | Ozone (O₃) | | Purge | | |
|---|---|---|---|---|---|---|---|---|---|---|
| | Substrate | Precursor | injection | Flow | | Flow | | Flow | | |
| Source | Temp. | heating | Time | rate | Time | rate | Time | rate | Time | No. of |
| Unit | ° C. | ° C. | (sec) | (sccm) | (sec) | (sccm) | (sec) | (sccm) | (sec) | depositions |
| Ex. 2 | 400 | 65 | 8 | 1,000 | 1 | 1,000 | 4 | 1,000 | 1 | 1,100 |

The thin film deposited in the above manner was analyzed for the composition of the silicon oxide thin film by AES (Auger Electron Spectroscopy) using X-ray photoelectron spectroscopy. The results are shown in FIG. 10.

As shown in FIG. 10, the thin film deposited using the silicon precursor compound prepared according to the present invention was a silicon oxide thin film with high purity.

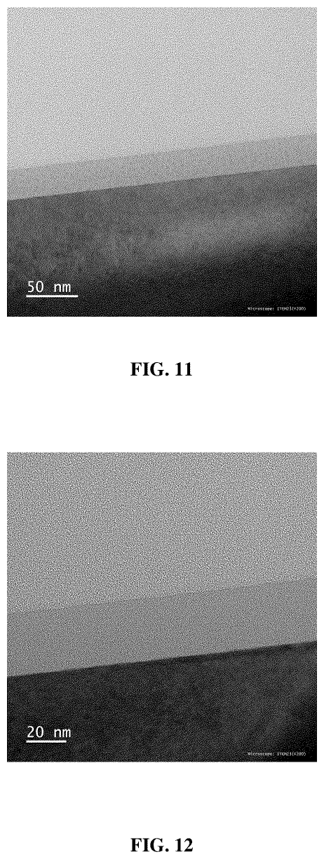

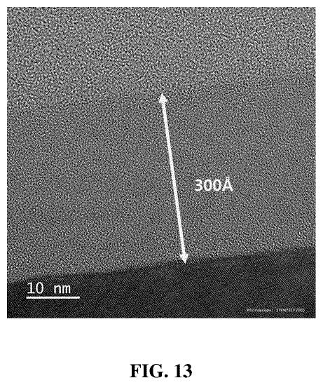

In addition, the step coverage and thickness of the silicon oxide thin film were observed using a transmission electron microscope (TEM) as shown in FIGS. 11 to 13.

Table 2 below shows the results of analyzing the characteristics of the specific silicon oxide thin film.

TABLE 2

| | Substrate | | Film | O/Si |
|---|---|---|---|---|
| | temp. | Deposition rate | thickness | Composition |
| Source | ° C. | Å/cycle | Å | ratio |
| Example 2 | 400 | 0.27 | 300 | 1.78 |

As shown in Table 2, a thick film with a thickness of 300 Å was formed at a high deposition rate at a substrate temperature of 400° C. and a deposition rate of 0.27 Å/cycle. The O/Si composition ratio of the formed thin film indicated that a silicon-containing thin film with high purity was formed.

As described above, the silicon precursor compound prepared according to the present invention is suitable for forming a silicon-containing thin film with high purity at a high deposition rate through atomic layer deposition (ALD).

The above-described embodiments are only for the purpose of describing the preferred embodiments of the present invention. The scope of the present invention is not limited to the described embodiments. Various changes, modifications, or substitutions will be possible by those skilled in the art within the technical idea and claims of the present invention. It should be understood that such embodiments fall within the scope of the present invention.

1. A silicon precursor compound represented by the following Formula 1: 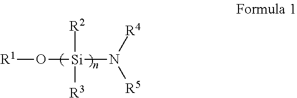
wherein n is 1 or 2,
R¹ is selected from a linear or branched, saturated or unsaturated hydrocarbon group having 1 to 4 carbon atoms, an isomer thereof, and NR⁷R⁸,
R² and R³ are each individually selected from hydrogen (H), chlorine (Cl), methyl (Me), methoxy (MeO), ethoxy (EtO), n-propoxy, isopropoxy (^{iso}PrO), n-butoxy, isobutoxy (^{iso}BuO), sec-butoxy (^{sec}BuO), tert-butoxy (^{tert}BuO), and NR⁷R⁸,
R⁴ is a linear or branched, saturated or unsaturated hydrocarbon group or an isomer thereof,
R⁵ is selected from methyl (Me), ethyl (Et), iso-propyl (^{iso}Pr), SiMe₃, SiHMe₂, SiH₂Me, SiH₃, SiHClMe, SiHCl₂, SiMe₂CH₂CH₃, SiMe₂CH═CH₂, and SiHMeCH═CH₂, and
R⁷ and R⁸ in NR⁷R⁸ are each individually selected from methyl (Me), ethyl (Et), and iso-propyl (^{iso}Pr).

2. The silicon precursor compound of claim 1, which is selected from the group consisting of the following compounds (1) to (56):

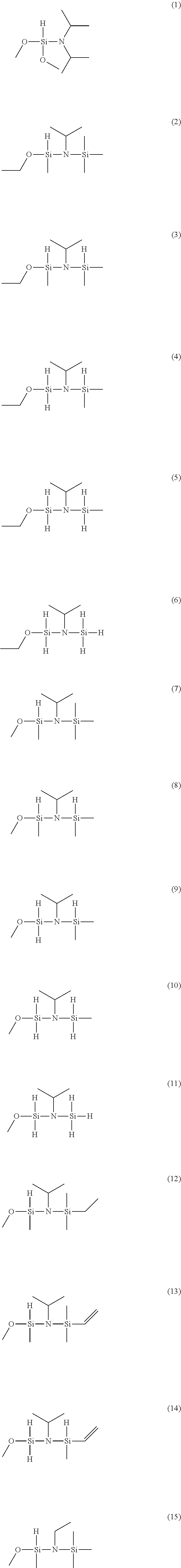

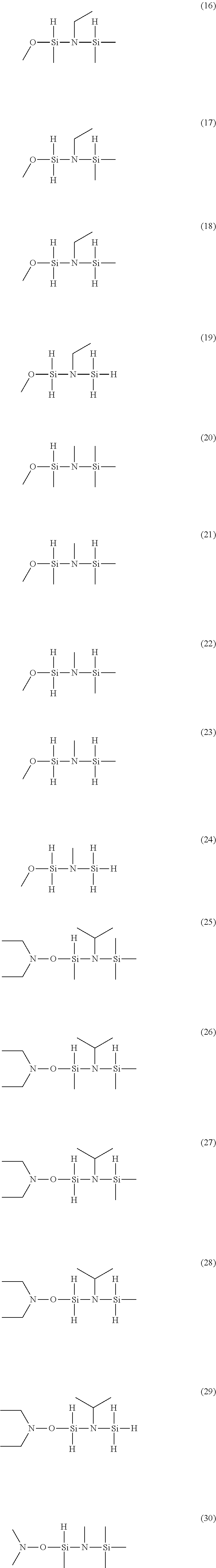

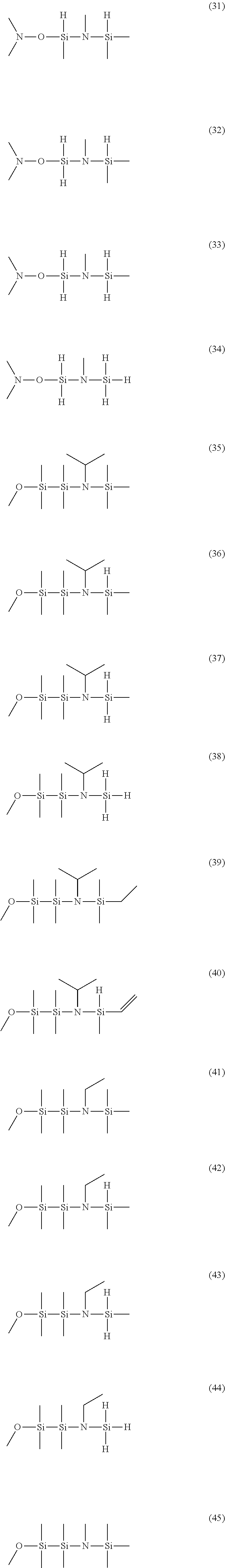

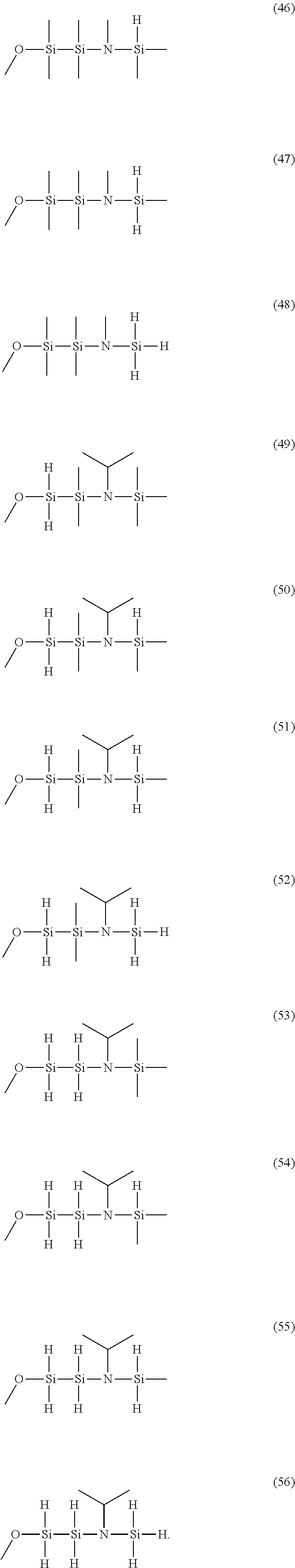

3. A method for preparing a silicon precursor compound, which comprises reacting an alkoxide compound with either a secondary amine or an alkylaminosilane to prepare a silicon precursor compound represented by the following Formula 1: 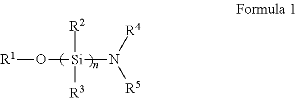
wherein n is 1 or 2,
R¹ is any one selected from a linear or branched, saturated or unsaturated hydrocarbon group having 1 to 4 carbon atoms, an isomer thereof, and NR⁷R⁸,
R² and R³ are each individually selected from hydrogen (H), chlorine (Cl), methyl (Me), methoxy (MeO), ethoxy (EtO), n-propoxy, isopropoxy (^{iso}PrO), n-butoxy, isobutoxy (^{iso}BuO), sec-butoxy (^{sec}BuO), tert-butoxy (^{tert}BuO), and NR⁷R⁸,
R⁴ is a linear or branched, saturated or unsaturated hydrocarbon group or an isomer thereof,
R⁵ is selected from methyl (Me), ethyl (Et), iso-propyl (^{iso}Pr), SiMe₃, SiHMe₂, SiH₂Me, SiH₃, SiHClMe, SiHCl₂, SiMe₂CH₂CH₃, SiMe₂CH═CH₂, and SiHMeCH═CH₂, and
R⁷ and R⁸ in NR⁷R⁸ are each individually selected from methyl (Me), ethyl (Et), and iso-propyl (^{iso}Pr).

4. The method for preparing a silicon precursor compound of claim 3, wherein the alkoxide compound is a compound represented by the following Formula 4: 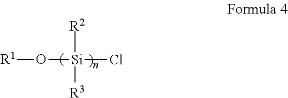
wherein n is 1 or 2,
R¹ is selected from a linear or branched, saturated or unsaturated hydrocarbon group having 1 to 4 carbon atoms, an isomer thereof, and NR⁷R⁸,
R² and R³ are each individually selected from hydrogen (H), chlorine (Cl), methyl (Me), methoxy (MeO), ethoxy (EtO), n-propoxy, isopropoxy (^{iso}PrO), n-butoxy, isobutoxy (^{iso}BuO), sec-butoxy (^{sec}BuO), tert-butoxy (^{tert}BuO), and NR⁷R⁸,
and R⁷ and R⁸ in NR⁷R⁸ are each individually selected from methyl (Me), ethyl (Et), and iso-propyl (^{iso}Pr).

5. The method for preparing a silicon precursor compound of claim 3, wherein the reaction of the alkoxide compound with the secondary amine prepares a silicon precursor compound represented by the following Formula 8: 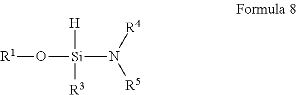
wherein R¹ is selected from a linear or branched, saturated or unsaturated hydrocarbon group having 1 to 4 carbon atoms, an isomer thereof, and NR⁷R⁸,
R³ is selected from hydrogen (H), chlorine (Cl), methyl (Me), methoxy (MeO), ethoxy (EtO), n-propoxy, isopropoxy (^{iso}PrO), n-butoxy, isobutoxy (^{iso}BuO), sec-butoxy (^{sec}BuO), tert-butoxy (^{tert}BuO), and NR⁷R⁸,
R⁴ is a linear or branched, saturated or unsaturated hydrocarbon group or an isomer thereof,
R⁵ is selected from methyl (Me), ethyl (Et), iso-propyl (^{iso}Pr), SiMe₃, SiHMe₂, SiH₂Me, SiH₃, SiHClMe, SiHCl₂, SiMe₂CH₂CH₃, SiMe₂CH═CH₂, and SiHMeCH═CH₂, and
R⁷ and R⁸ in NR⁷R⁸ are each individually selected from methyl (Me), ethyl (Et), and iso-propyl (^{iso}Pr).

6. The method for preparing a silicon precursor compound of claim 3, wherein the reaction of the alkoxide compound with the alkylaminosilane prepares a silicon precursor compound represented by the following Formula 15 or Formula 18: 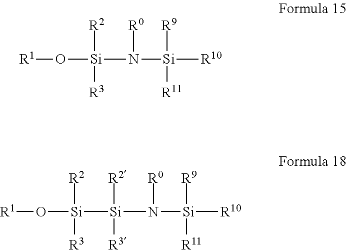
wherein R¹ is selected from a linear or branched, saturated or unsaturated hydrocarbon group having 1 to 4 carbon atoms, an isomer thereof, and NR⁷R⁸,
R², R¹, R³, and R^{3′} are each individually selected from hydrogen (H), chlorine (Cl), methyl (Me), methoxy (MeO), ethoxy (EtO), n-propoxy, isopropoxy (^{iso}PrO), n-butoxy, isobutoxy (^{iso}BuO), sec-butoxy (^{sec}BuO), tert-butoxy (^{tert}BuO), and NR⁷R⁸,
R⁰ is a linear or branched, saturated or unsaturated hydrocarbon group or an isomer thereof,
R⁹, R¹⁰, and R¹¹ are each individually selected from hydrogen (H), chlorine (Cl), a methyl group (Me), an ethyl group (CH₂CH₃), and a vinyl group (CH═CH₂), and
R⁷ and R⁸ in NR⁷R⁸ are each individually selected from methyl (Me), ethyl (Et), and iso-propyl (^{iso}Pr).

7. The method for preparing a silicon precursor compound of claim 3, wherein the silicon precursor compound is selected from the group consisting of the following compounds (1) to (56):

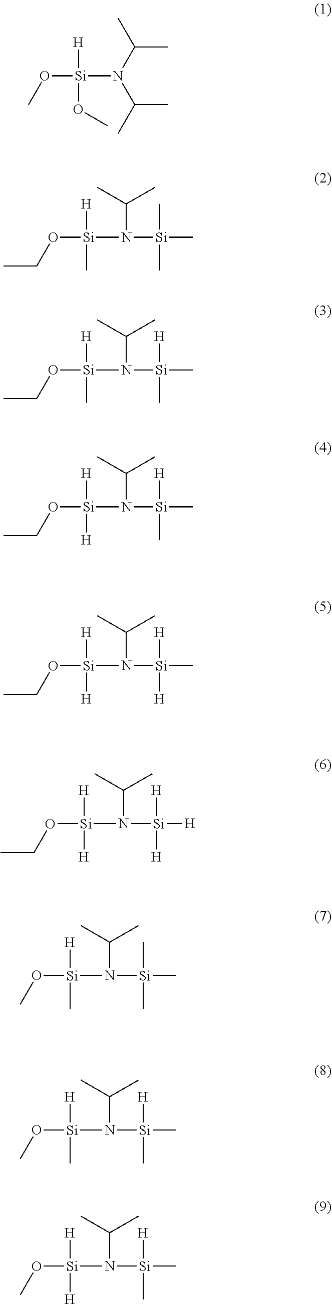

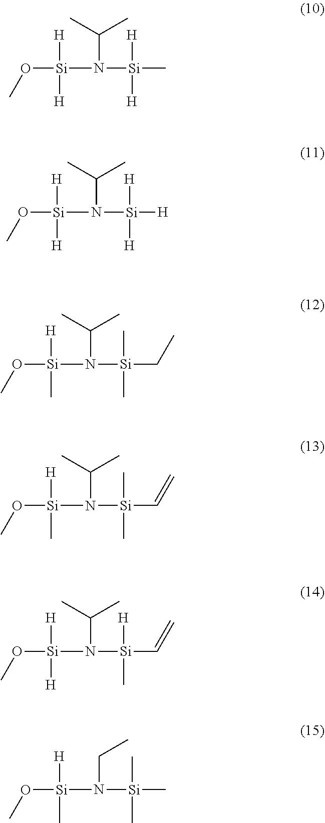

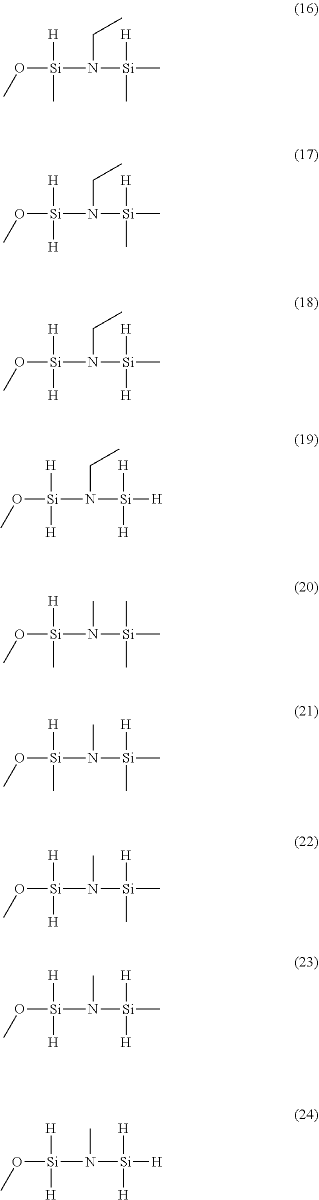

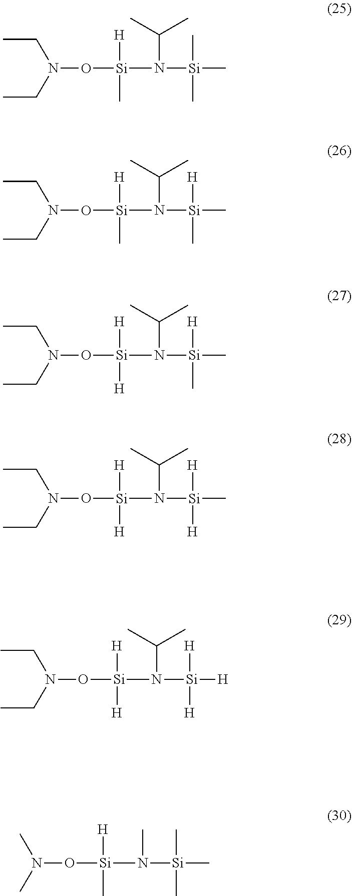

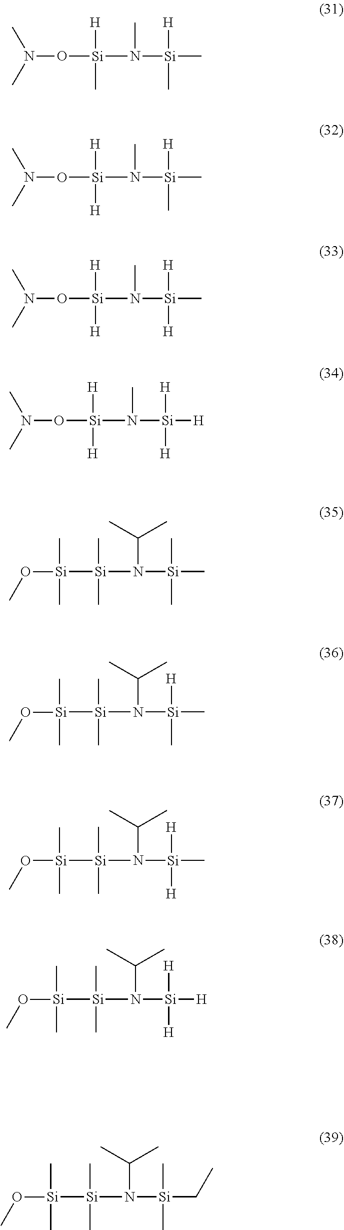

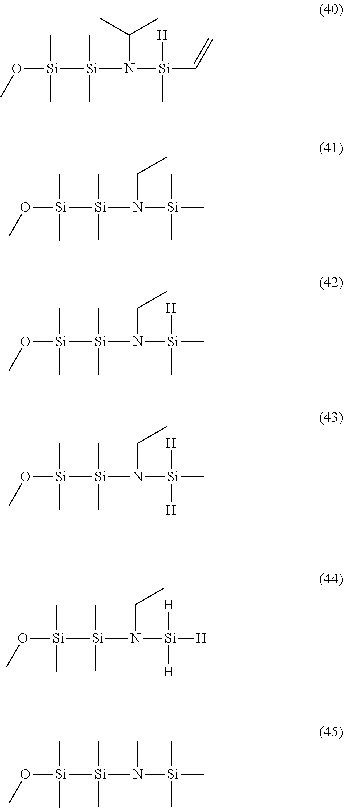

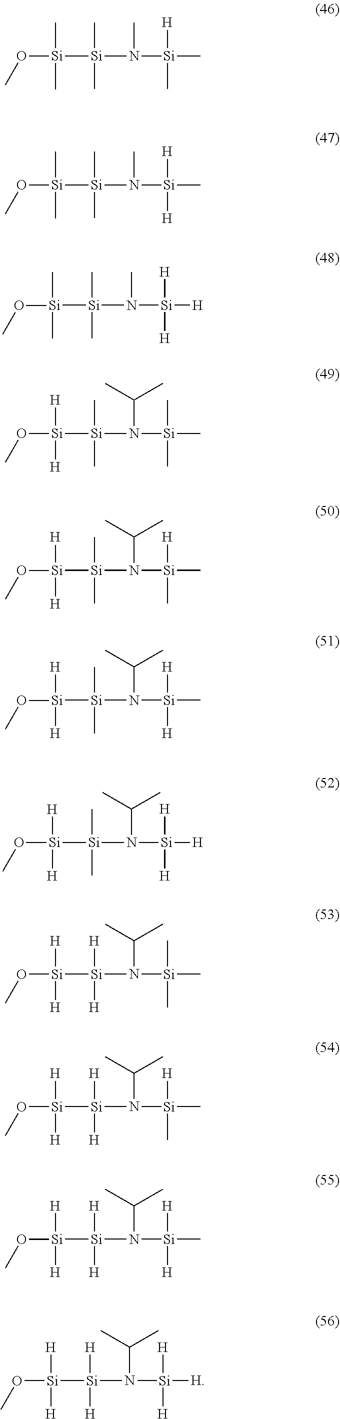

8. A method for preparing a silicon-containing thin film, wherein the silicon-containing thin film is formed using a silicon precursor compound represented by the following Formula 1: 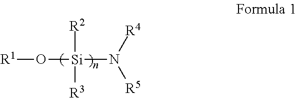
wherein n is 1 or 2,
R¹ is selected from a linear or branched, saturated or unsaturated hydrocarbon group having 1 to 4 carbon atoms, an isomer thereof, and NR⁷R⁸,
R² and R³ are each individually selected from hydrogen (H), chlorine (Cl), methyl (Me), methoxy (MeO), ethoxy (EtO), n-propoxy, isopropoxy (^{iso}PrO), n-butoxy, isobutoxy (^{iso}BuO), sec-butoxy (^{sec}BuO), tert-butoxy (^{tert}BuO), and NR⁷R⁸,
R⁴ is a linear or branched, saturated or unsaturated hydrocarbon group or an isomer thereof,
R⁵ is selected from methyl (Me), ethyl (Et), iso-propyl (^{iso}Pr), SiMe₃, SiHMe₂, SiH₂Me, SiH₃, SiHClMe, SiHCl₂, SiMe₂CH₂CH₃, SiMe₂CH═CH₂, and SiHMeCH═CH₂, and
R⁷ and R⁸ in NR⁷R⁸ are each individually selected from methyl (Me), ethyl (Et), and iso-propyl (^{iso}Pr).

9. The method for preparing a silicon-containing thin film of claim 8, wherein the silicon precursor compound is selected from the group consisting of the following compounds (1) to (56):

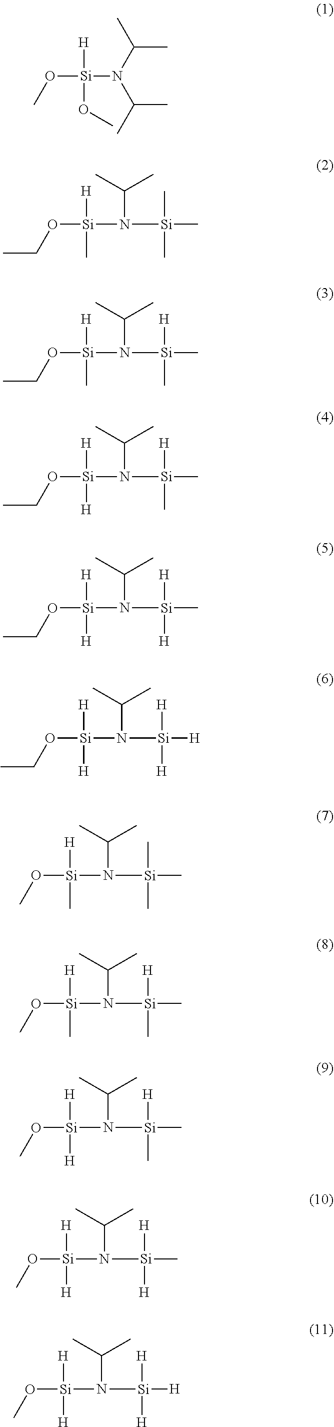

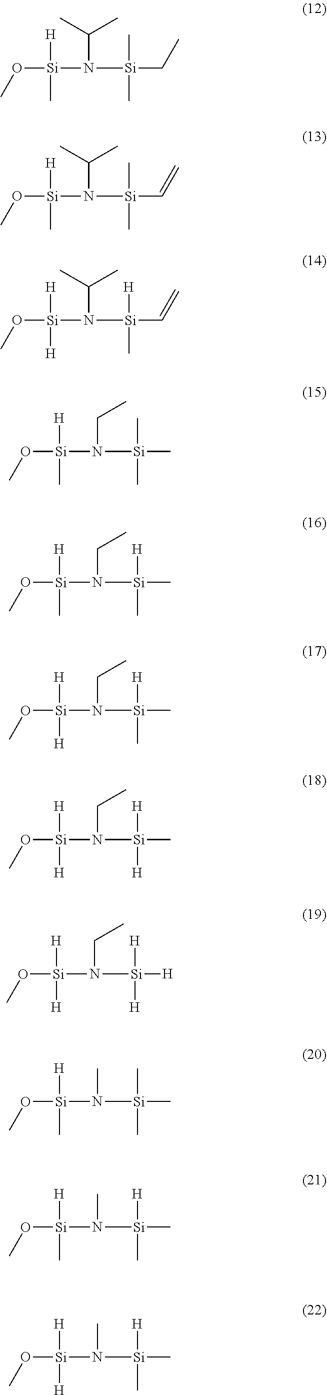

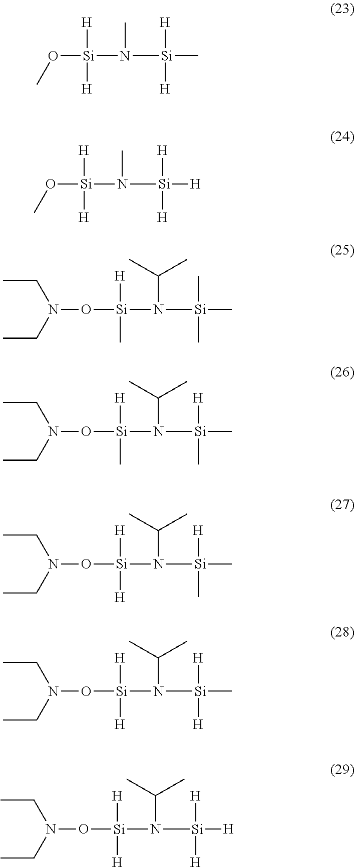

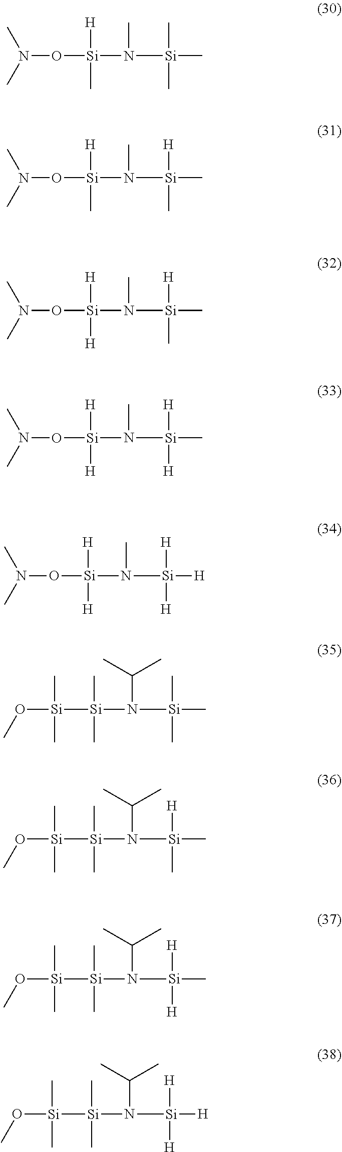

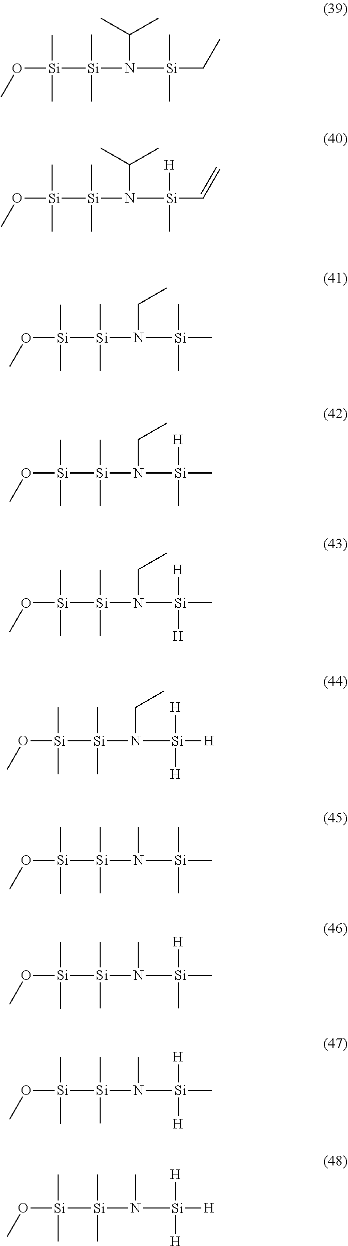

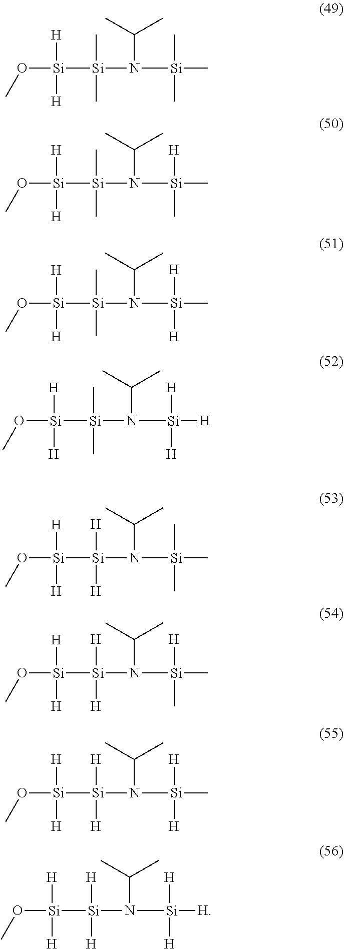

10. The method for preparing a silicon-containing thin film of claim 8, wherein the silicon-containing thin film is deposited by chemical vapor deposition, plasma-enhanced chemical vapor deposition, or atomic layer deposition.

11. The method for preparing a silicon-containing thin film of claim 8, wherein the silicon-containing thin film is selected from the group consisting of a silicon oxide (SiO₂) film, a silicon oxycarbide (SiOC) film, a silicon nitride (SiN) film, a silicon oxynitride (SiON) film, a silicon carbonitride (SiCN) film, a silicon oxycarbonitride (SiOCN) film, and a silicon carbide (SiC) film.

12. The method for preparing a silicon-containing thin film of claim 10, wherein the silicon-containing thin film is a silicon oxide (SiO₂) film, and wherein the silicon oxide film is deposited by atomic layer deposition, and the atomic layer deposition comprises:
providing a substrate in a reactor;
feeding the silicon precursor compound to the reactor;
purging the reactor with a purge gas;
feeding an oxygen source to the reactor to react with the silicon precursor compound to form the silicon oxide film; and
purging the reactor with a purge gas.

13. The method for preparing a silicon-containing thin film of claim 12, wherein the purge gas is selected from the group consisting of nitrogen, helium, argon, and mixtures thereof, and
the oxygen source is selected from the group consisting of oxygen, peroxide, oxygen plasma, water vapor, water vapor plasma, hydrogen peroxide, ozone source, and mixtures thereof.

14. The method for preparing a silicon-containing thin film of claim 12, wherein the oxygen source is ozone (O₃).

15. The method for preparing a silicon-containing thin film of claim 12, wherein the method is carried out with a substrate temperature of about 200° C. to about 600° C.
